(19) United States
(12) Patent Application Publication
(10) Pub. No.: US 2017/0005091 A1
(43) Pub. Date: Jan. 5, 2017

(54) Semiconductor Devices and Method for Forming Semiconductor Devices

(71) Applicant: Infineon Technologies Austria AG, Villach (AT)

(72) Inventors: Ravi Keshav Joshi, Villach (AT); Johannes Baumgartl, Riegersdorf (AT); Christoph Gruber, Wernberg (AT); Andreas Haghofer, Villach (AT); Martin Poelzl, Ossiach (AT); Juergen Steinbrenner, Noetsch (AT)

(21) Appl. No.: 15/196,999

(22) Filed: Jun. 29, 2016

(30) Foreign Application Priority Data
Jun. 30, 2015 (DE) 102015110490.3

(51) Int. Cl. H01L 27/088; H01L 29/66; H01L 29/417; H01L 29/08; H01L 29/10; H01L 29/78

(52) U.S. Cl. CPC H01L 27/0886; H01L 29/1095; H01L 29/7851; H01L 29/41791; H01L 29/0847; H01L 29/41775; H01L 29/66795

(57) ABSTRACT

A semiconductor device includes a semiconductor laminar structure arranged on a semiconductor substrate. The semiconductor laminar structure includes a first doping region of a field effect transistor structure and at least a part of a body region of the field effect transistor structure. The body region has a first conductivity type and the first doping region has a second conductivity type. The semiconductor device further includes an electrically conductive contact structure providing an electrical contact to the first doping region of the field effect transistor structure and to the body region of the field effect transistor structure at one or more sidewalls of the semiconductor laminar structure.

### PRIORITY CLAIM

This application claims priority to German Patent Application No. 10 2015 110 490,3 filed on 30 Jun. 2015, the content of said application incorporated herein by reference in its entirety.

### TECHNICAL FIELD

Embodiments relate to transistor structures and in particular to semiconductor devices and a method for forming a semiconductor device.

### BACKGROUND

Transistor devices having smaller active channel lengths or gate lengths may experience higher current density per area (or volume) or higher leakage currents. Smaller transistors devices may also experience short channel effects, hot electrons, drain induced barrier lowering (DIBL), or high leakage currents, for example. These may lead to increased instances of device failure and decreased device reliability, for example.

It is a demand to provide a concept for semiconductor devices which enable an improvement of reliability of the semiconductor device.

### SUMMARY

Some embodiments relate to a semiconductor device. The semiconductor device comprises a semiconductor laminar structure arranged on a semiconductor substrate. The semiconductor laminar structure comprises a first doping region of a field effect transistor structure and at least a part of a body region of the field effect transistor structure. The body region comprises a first conductivity type and the first doping region comprises a second conductivity type. The semiconductor device comprises an electrically conductive contact structure providing an electrical contact to the first doping region of the field effect transistor structure and to the body region of the field effect transistor structure at at least one sidewall of the semiconductor laminar structure.

Some embodiments relate to a further semiconductor device. The semiconductor device 200 comprises a semiconductor laminar structure arranged on a semiconductor substrate. The semiconductor laminar structure comprises a first doping region of a field effect transistor structure and at least a part of a body region of the field effect transistor structure. The body region comprises a first conductivity type and the first doping region comprises a second conductivity type. The semiconductor substrate comprises a second doping region of the field effect transistor structure The second doping region comprises a second conductivity type. A minimum lateral dimension of the semiconductor laminar structure is less than 200 nm.

Some embodiments relate to a method for forming a semiconductor device. The method comprises forming a gate structure of a field effect transistor structure on at least one sidewall of the semiconductor laminar structure. The method further comprises forming an electrically conductive contact structure in contact with a doping region of the field effect transistor structure in the semiconductor laminar structure at the sidewall of the semiconductor laminar structure.

Those skilled in the art will recognize additional features and advantages upon reading the following detailed description, and upon viewing the accompanying drawings.

### BRIEF DESCRIPTION OF THE FIGURES

Some embodiments of apparatuses and/or methods will be described in the following by way of example only, and with reference to the accompanying figures, in which:

FIG. 1 shows a schematic illustration of a semiconductor device;

FIG. 2 shows a schematic illustration of a further semiconductor device;

FIG. 3 shows a schematic illustration of a further semiconductor device having a plurality of semiconductor laminar structures;

FIGS. 4A to 4F show schematic illustrations of a method for forming at least one semiconductor laminar structure;

FIGS. 5A to 5C show micrographs of a method for forming at least one semiconductor laminar structure;

FIG. 6 shows a flow chart of a method for forming a semiconductor device; and

FIGS. 7A to 7P show schematic illustrations of a method for forming a semiconductor device.

### DETAILED DESCRIPTION

Various example embodiments will now be described more fully with reference to the accompanying drawings in which some example embodiments are illustrated. In the figures, the thicknesses of lines, layers and/or regions may be exaggerated for clarity.

Accordingly, while example embodiments are capable of various modifications and alternative forms, embodiments thereof are shown by way of example in the figures and will herein be described in detail. It should be understood, however, that there is no intent to limit example embodiments to the particular forms disclosed, but on the contrary, example embodiments are to cover all modifications, equivalents, and alternatives falling within the scope of the disclosure. Like numbers refer to like or similar elements throughout the description of the figures.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Unless otherwise defined, all terms (including technical and scientific terms) used herein have the same meaning as commonly understood by one of ordinary skill in the art to which example embodiments belong. It will be further understood that terms, e.g., those defined in commonly used dictionaries, should be interpreted as having a meaning that is consistent with their meaning in the context of the relevant art. However, should the present disclosure give a specific meaning to a term deviating from a meaning commonly understood by one of ordinary skill, this meaning is to be taken into account in the specific context this definition is given herein.

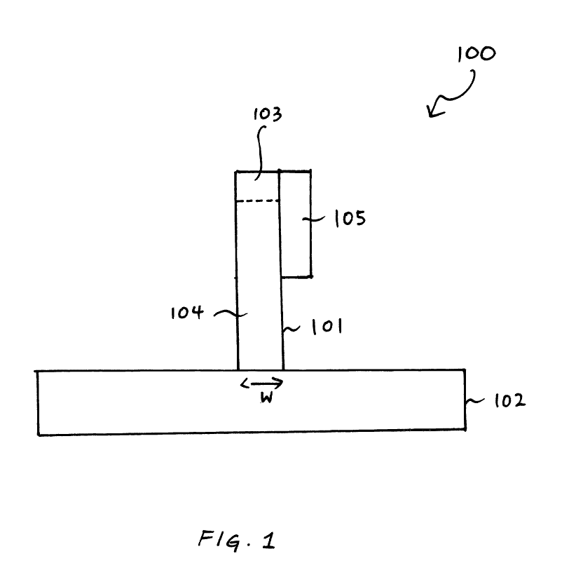

FIG. 1 shows a schematic illustration of a semiconductor device 100 according to an embodiment.

The semiconductor device 100 comprises a semiconductor laminar structure 101 arranged on a semiconductor substrate 102. The semiconductor laminar structure 101 further comprises a first doping region 103 of a field effect transistor structure and at least a part of a body region 104 of the field effect transistor structure. The body region 104 comprises a first conductivity type and the first doping region 103 comprises a second conductivity type. The semiconductor device 100 further comprises an electrically conductive contact structure 105 providing an electrical contact to the first doping region 103 of the field effect transistor structure and to the body region 104 of the field effect transistor structure at at least one sidewall of the semiconductor laminar structure 101.

Due to the electrically conductive contact structure 105 being formed at one or more sidewalls of the semiconductor laminar structure 101, afield effect transistor structure which is more reliable may be obtained. For example, the semiconductor device 100 may provide a small mesa concept in the channel region to fully deplete the device and lower leakage currents. In addition, short channel effects, hot electrons, drain induced barrier lowering (DIBL) and high leakage currents may be reduced or avoided, for example.

The semiconductor laminar structure 101 may be a structure located or formed on the (first) lateral surface of the semiconductor substrate 102, for example. The semiconductor laminar structure 101 may be a plate or a fin structure extending substantially vertically from the (first) lateral surface of the semiconductor substrate 102, for example. For example, the semiconductor laminar structure 101 may be a pillar structure or a column structure (e.g. in a cross-section) formed on the (first) lateral surface of the semiconductor substrate 102. For example, the semiconductor laminar structure 101 may be a rectangular cuboidal structure or a fin structure, for example.

The semiconductor laminar structure 101 may have a first lateral dimension (width, W) and second lateral dimension (length), for example. The first lateral dimension (width) may be smaller than (or equal to) the second lateral dimension (length), for example. The first lateral dimension of the semiconductor laminar structure 101 may be a minimum lateral dimension of the semiconductor laminar structure 101, for example. For example, the minimum lateral dimension of the semiconductor laminar structure 101 may be less than 200 nm (or e.g. less than 180 nm, or less than 150 nm). The first lateral dimension or the minimum lateral dimension may be the smallest distance between a first sidewall of the semiconductor laminar structure 101 and a second opposite sidewall of the semiconductor laminar structure 101, for example. For example, the first lateral dimension or the minimum lateral dimension may be the smallest lateral dimension of the semiconductor laminar structure 101 measured in a direction substantially parallel to the (first) lateral surface of the semiconductor substrate 102.

The second lateral dimension of the semiconductor laminar structure 101 may be a maximal lateral dimension of the semiconductor laminar structure 101, for example. The second lateral dimension of the semiconductor laminar structure 101 may be larger than the first lateral dimension of the semiconductor laminar structure 101, for example. For example, the second lateral dimension of the semiconductor laminar structure 101 may be more than five times (or e.g. more than ten times, or e.g. more than hundreds of times) larger than the first lateral dimension of the semiconductor laminar structure 101. For example, the second lateral dimension of the semiconductor laminar structure 101 may lie between 1 μm and 1 mm, (or e.g. between 1 μm and 500 μm). The second lateral dimension of the semiconductor laminar structure 101 may be a distance measured in a direction substantially parallel to the (first) lateral surface of the semiconductor substrate 102, for example. The second lateral dimension of the semiconductor laminar structure 101 may be a distance measured in a direction substantially perpendicularly to the first lateral dimension, for example. The second lateral dimension of the semiconductor laminar structure 101 may be a lateral dimension of the semiconductor laminar structure 101 measured substantially parallel to a first sidewall of the semiconductor laminar structure 101 or substantially parallel to a second sidewall of the semiconductor laminar structure 101, for example.

The semiconductor laminar structure 101 may have a minimum height of at least 300 nm, for example. For example, a minimum height of the semiconductor laminar structure 101 may lie between 300 nm and 2 μm, (or e.g. between 500 nm and 1 μm). The minimum height of the semiconductor laminar structure 101 may be the smallest height of the semiconductor laminar structure 101 measured in a direction substantially perpendicular to the (first) lateral surface of the semiconductor substrate 102 on which the semiconductor laminar structure 101 is formed, for example. For example, the minimum height of the semiconductor laminar structure 101 may be a smallest distance measured between a top wall of the semiconductor laminar structure 101 and the (first) lateral surface of the semiconductor substrate 102, for example.

The semiconductor laminar structure 101 may be a fin (or pillar) structure having the first sidewall and the second sidewall, for example. A top wall of the semiconductor laminar structure 101 may lie between the first sidewall of the semiconductor laminar structure 101 and the second sidewall of the semiconductor laminar structure 101, for example. For example, the top wall of the semiconductor laminar structure 101 may join or connect the first sidewall of the semiconductor laminar structure 101 and the second sidewall of the semiconductor laminar structure 101.

The semiconductor laminar structure 101 may include or be formed from a semiconductor material, for example, the semiconductor material of the semiconductor laminar structure 101 may be a silicon-based semiconductor material, a silicon carbide-based semiconductor material, a gallium arsenide-based semiconductor material or a gallium nitride-based semiconductor material. For example, the semiconductor material of the semiconductor laminar structure 101 may be silicon (or epitaxial silicon), for example. The semiconductor laminar structure 101 may be an epitaxial grown structure formed on the first surface of the semiconductor substrate 102, for example.

The semiconductor substrate 102 on which the semiconductor laminar structure 101 is formed (or grown or connected to) may be part of a semiconductor wafer, for example. For example, the semiconductor substrate material may be a silicon-based semiconductor substrate material, a silicon carbide-based semiconductor substrate material, a gallium arsenide-based semiconductor substrate material or a gallium nitride-based semiconductor substrate material. For example, the semiconductor material of the semiconductor laminar structure 101 may be silicon.

The semiconductor device 100 may include at least one field effect transistor structure (e.g. one or more field effect transistor structures or e.g. a plurality of field effect transistor structures). Each field effect transistor (FET) structure may include at least a (first) doping region, a body region 104 and a further (or second) doping region, for example. The field effect transistor structure may include or be a metal oxide semiconductor field effect transistor (MOSFET) structure, for example. In a MOSFET structure, the (first) doping region may be a (first) source/drain region and the further (second) doping region may be a (second) source/drain region, for example. Alternatively, the field effect transistor structure may include an insulated gate bipolar transistor (IGBT) structure, for example. In an IGBT structure, the (first) doping region may be a (first) emitter region and the further (second) doping region may be a drift region of the IGBT structure, for example. An IGBT structure may further include a third doping region which may be a collector region, for example.

The semiconductor laminar structure 101 may include at least part of a body region 104 of a FET structure, for example. For example, the body region 104 of the FET structure may be a doped semiconductor region formed in the semiconductor laminar structure 101, for example. The body region 104 of the FET structure may have a doping of a first conductivity type, for example. The doped body region 104 of the first conductivity type may be a p-type doped semiconductor region, for example. For example, the majority charge carriers in a p-type doped semiconductor region may be holes. The part of the body region 104 in the semiconductor laminar structure 101 may have an average doping concentration of at least 1×10¹⁷ dopant atoms per cm³ (or e.g. between 1×10¹⁷ dopant atoms per cm³ and 1×10¹⁸ dopant atoms per cm³). The average doping concentration may be a measured number of dopant atoms (e.g. acceptor dopant atoms) per volume averaged over a region of interest of the body region 104, for example.

A region comprising the first conductivity type may be a p-doped region (e.g. caused by incorporating aluminum ions or boron ions) or an n-doped region (e.g. caused by incorporating nitrogen ions, phosphor ions or arsenic ions). Consequently, the second conductivity type indicates an opposite n-doped region or p-doped region. For example, the first conductivity type may indicate an n-doping and the second conductivity type may indicate a p-doping or vice-versa.

The semiconductor laminar structure 101 may further include a (first) doping region of a FET structure, for example. For example, the (first) doping region of the FET structure may be a doped semiconductor region formed in the semiconductor laminar structure 101, for example. The (first) doping region of the FET structure may have a doping of a second conductivity type, for example. The (first) doping region of the second conductivity type may be an n-type doped semiconductor region, for example. For example, the majority charge carriers in an n-type doped semiconductor region may be electrons. The (first) doping region of the FET structure may have an average doping concentration of at least 1×10¹⁷ dopant atoms per cm³ (or e.g. between 1×10¹⁷ dopant atoms per cm³ and 1×10¹⁸ dopant atoms per cm³). The average doping concentration may be a measured number of dopant atoms (e.g. donor dopant atoms) per volume averaged over a region of interest of the (first) doping region of the FET structure, for example.

The electrically conductive contact structure 105 may be formed on the first sidewall of the semiconductor laminar structure 101 and/or on the second sidewall of the semiconductor laminar structure 101. The electrically conductive contact structure 105 may extend along the semiconductor laminar structure 101 from a first sidewall of the semiconductor laminar structure 101 to the second sidewall of the semiconductor laminar structure 101, for example. For example, part of the electrically conductive contact structure 105 may be formed on the top wall of the semiconductor laminar structure 101.

The electrically conductive contact structure 105 may be in contact with the first doping region of the FET structure at the top wall of the semiconductor laminar structure 101. Optionally or additionally, a part of the electrically conductive contact structure 105 in contact with the first doping region may cover the top wall of the semiconductor laminar structure 101, for example. The electrically conductive contact structure 105 may be configured to provide electrical signals (e.g. current signals or voltage signals) to the (first) doping region of the FET structure, for example.

A portion of the electrically conductive contact structure 105 may be arranged on the one or more sidewalls (e.g. on a first sidewall and on a second sidewall) of the semiconductor laminar structure 101. The portion of the electrically conductive contact structure 105 arranged at or on the sidewall may have a (shorting) contact area with the (first) doping region of the FET structure and the body region 104 of the FET structure, for example. For example, the portion of the electrically conductive contact structure 105 arranged at or on the sidewall may provide a short circuit between the portion of the body region 104 and the (first) doping region of the ITT structure. The electrical contact or short circuit may be referred to as a source-body short, for example. For example, the (shorted) portion of the doping region of the FET structure and the (shorted) portion of the body region 104 of the FET structure may be arranged between the portion of the first sidewall of the semiconductor laminar structure 101 and the portion of the second sidewall of the semiconductor laminar structure 101 on which the contact area of the electrically conductive contact structure 105 is formed.

The portion of the electrically conductive contact structure 105 arranged on the sidewalls of the semiconductor laminar structure 101 may have a minimal lateral dimension which lies between 150 nm and 300 nm (e.g. 200 nm), for example. For example, the minimal lateral dimension of the contact area of the electrically conductive contact structure 105 with the (first) doping region of the FET structure and the body region 104 of the FET structure (e.g. the shorting contact area) may lie between 150 nm and 300 nm (e.g. 200 nm). The minimal lateral dimension of the contact area may be a smallest distance measured in a direction parallel to the sidewall of the semiconductor laminar structure 101 from a first side of the portion of the electrically conductive contact structure 105 in contact with the (first) doping region of the FET structure and the body region 104 of the FET structure and a second side of the portion of the electrically conductive contact structure 105 in contact with the (first) doping region of the FET structure and the body region 104, for example.

Additionally, or optionally, the electrically conductive contact structure 105 may include a plurality of lateral separated (electrically conductive) contact areas with the body region 104 and the first doping region 103 of the field effect transistor structure. The plurality of contact areas may be arranged at (or on) the one or more sidewalls of the semiconductor laminar structure 101. For example, a minimal lateral distance between neighboring contact areas of the plurality of contact areas (which the electrically conductive contact structure 105 has with the body region 104 and the first doping region 103 of the field effect transistor structure) may lie between 100 nm and 1 μm (or e.g. between 100 nm and 500 nm). The minimal lateral distance may be the smallest distance between consecutive electrically conductive contact areas, for example. Each contact area of the plurality of contact areas may be separated by at least the minimal lateral distance, for example.

Additionally, alternatively or optionally, neighboring (shorting) contact areas of the plurality of contact areas may be laterally separated by a lateral distance of

$$\frac{{V}_{BD}}{100} 10 nm .$$

For example, V_{BD} may be a value representing a breakdown voltage of the semiconductor device 100. The breakdown voltage, V_{BD,} may be a maximum (or largest) voltage that may be provided between a (first) doping region of the FET structure and a (second) doping region of the FET structure without the FET structure being damaged, for example. Optionally, the breakdown voltage, V_{BD,} may be a maximum (or largest) reverse voltage of the FET structure (e.g. for a BJT FET structure), for example. For example, a breakdown voltage, V_{BD,} of the semiconductor device 100 may be more than 100 V, (or e.g. more than 1000 V). For example, a breakdown voltage, V_{BD}, of the semiconductor device 100 may lie between 100 V and 2000 V (or e.g. between 100 V and 1000 V or e.g. between 100 V and 800 V).

The semiconductor device 100 may further include at least one gate structure arranged on the one or more sidewalls of the semiconductor laminar structure 101. For example, a first gate structure may be arranged on the (first) sidewall of the (or each) semiconductor laminar structure 101 and a second gate structure may be arranged on the (second) sidewall of the (or each) semiconductor laminar structure 101, for example. The first gate structure and the second gate structure may form a multi-gate structure. Which may fully deplete a channel formed in the body region 104 between the first gate structure and the second gate structure, for example. For example, due to the minimum lateral dimension of the semiconductor laminar structure 101 being less than 200 nm, the body region of the semiconductor laminar structure 101 may be fully depleted of charges in an off state of the semiconductor device 100 (e.g. the semiconductor device 100 is a full-depleted or fully depletable device). For example, in an off state, the depletion zone may extend between a first sidewall of the semiconductor laminar structure 101 and a second sidewall of the semiconductor laminar structure 101 over the entire lateral dimension of the semiconductor laminar structure 101.

The gate structure may be arranged with a lateral offset to a contact area of the electrically conductive contact structure 105 with the body region 104 and the first doping region 103 of the field effect transistor structure at the one or more sidewalk of the semiconductor laminar structure 101). For example, the gate structure may be separated from the (shorting) contact area of the electrically conductive contact structure 105 with the body region 104 and the first doping region 103 at the sidewall of the semiconductor laminar structure 101 by a lateral offset of between 30 nm and 100 nm. Additionally, or optionally, the gate structure may be separated from the portion of the electrically conductive contact structure in contact with the first doping region 103 of the field effect transistor structure at the top wall of the semiconductor laminar structure 101 by a vertical offset of between 30 nm and 100 nm. The gate structure may be a conformal electrically conductive gate layer. The material of the gate structure may be polysilicon or tungsten, for example.

A conformal gate oxide layer (or material) may be formed directly on the semiconductor laminar structure 101 between the gate structure and the semiconductor laminar structure 101. The gate oxide layer may have a thickness of between 2 nm to 10 nm (or e.g. about 5 nm), for example. The material of the gate oxide layer may be silicon dioxide, for example.

Additionally, or optionally, the semiconductor device 100 may include a plurality of gate structures (e.g. a plurality of multi-gate structures). For example, a plurality of first gate structures may be formed on the (first) sidewall of the semiconductor laminar structure 101 and a plurality of second gate structures may be formed on the (second) sidewall of the semiconductor laminar structure 101.

A gate structure of the plurality of gate structures may be arranged laterally between the neighboring contact areas of the electrically conductive contact structure 105 with the body region and the first doping region of the field effect transistor structure. For example, a first gate structure formed on the (first) sidewall of the semiconductor laminar structure 101 may be arranged between neighboring contact areas of the plurality of contact areas of the electrically conductive contact structure 105 formed on the same (first) sidewall of the semiconductor laminar structure 101. Similarly, a second gate structure formed on the (second) sidewall of the semiconductor laminar structure 101 may be arranged between neighboring contact areas of the plurality of contact areas of the electrically conductive contact structure 105 formed on the same (second) sidewall of the semiconductor laminar structure 101.

Additionally, or optionally, at least part of the gate structure may be arranged or formed conformally on a surface of the semiconductor substrate 102 between neighboring semiconductor laminar structures 101, for example.

The semiconductor device 100 may include electrically insulating material arranged on the sidewalls of the semiconductor laminar structure 101, for example. A portion of the electrically insulating material may be arranged on the one or more sidewalls (e.g. on the sidewalls) of the semiconductor laminar structure 101 laterally between the gate structure and an adjacent (shorting) contact area of the electrically conductive contact structure 105 with the body region 104 and the first doping region 103 of the field effect transistor. The electrically insulating material may be located laterally between each gate structure of the plurality of gate structures and the adjacent (or neighboring) contact areas of the electrically conductive contact structure 105 with the body region 104 and the first doping region 103 of the field effect transistor, for example. For example, each gate structure may be separated or electrically insulated from adjacent contact areas of the electrically conductive contact structure 105 with the body region 104 and the first doping region 103 of the field effect transistor structure by the portion of the electrically insulating material located on the sidewalls of the semiconductor laminar structure 101.

A (further) portion of the electrically insulating material may be arranged on the one or more sidewalls (e.g. on the sidewalls) of the semiconductor laminar structure 101 between the gate structure and the portion of the electrically conductive contact structure 105 arranged on the top wall of the semiconductor laminar structure 101, for example. For example, the gate structure may be electrically insulated from the portion of the electrically conductive contact structure 105 at the top wall of the semiconductor laminar structure 101 by the electrically insulating material.

A (further) portion of the electrically insulating material may be arranged on the gate structures formed on the sidewalls of the semiconductor laminar structure 101, for example, the portion of the electrically insulating material arranged on the gate structures may encapsulate or embed the gate structures. The portion of the electrically insulating material arranged on the gate structures may be located in regions between neighboring semiconductor laminar structures 101, for example. The electrically insulating material may be silicon dioxide, high-density plasma chemical vapor deposition (HDP) oxide, and/or borophosphosilicate glass (BPSG), for example.

The electrically insulating material may be arranged between the plurality of gate structures and the plurality of contact areas of the electrically conductive contact structure 105 with the body region 104 and the first doping region 103 of the field effect transistor arranged on the semiconductor laminar structure 101. For example, the electrically insulating material may be arranged between the plurality of first gate structures formed on the (first) sidewall of the semiconductor laminar structure 101 and the plurality of contact areas of the electrically conductive contact structure 105 formed on the (first) sidewall of the semiconductor laminar structure 101. Additionally, or optionally, the electrically insulating material may be arranged between the plurality of second gate structures formed on the (second) sidewall of the semiconductor laminar structure 101 and the plurality of contact areas of the electrically conductive contact structure 105 formed on the (second) sidewall of the semiconductor laminar structure 101.

The second doping region of the FET structure may be located in the semiconductor substrate 102, for example. The second doping region of the FET structure may have a doping of a second conductivity type (e.g. n-type doping) and an average doping concentration of at least 1×10¹⁷ dopant atoms per cm³, (e.g. between 1×10¹⁷ dopant atoms per cm³ and 1×10¹⁸ dopant atoms per cm³), for example.

The semiconductor device 100 may include a second doping region contact structure arranged on a second opposite surface of the semiconductor substrate 102, for example. The second doping region contact structure may be a backside metallization layer, for example. The second doping region contact structure may be electrically connected to the second doping regions of at least one (e.g. or a plurality of FET structures) of the semiconductor device 100 formed in the semiconductor substrate 102 (or a third doping region or collector region formed in the semiconductor substrate 102 in the case of an IGBT structure).

The semiconductor device 100 may include an implant region formed in the semiconductor substrate 102. The implant region and the body region 104 located in the semiconductor laminar structure 101 may be ohmically connected to each other. For example, the implant region may form part of the body region 104 of the FET structure. For example, the implant region and the part of the body region 104 in the semiconductor laminar structure 101 may be of the same conductivity type. A minimal lateral dimension of the implant region may be larger than a minimal lateral dimension of the semiconductor laminar structure 101, for example. The implant region may have a higher doping concentration than the part of the body region 104 located in the semiconductor laminar structure 101. For example, the implant region may have a doping of a first conductivity type (e.g. p+ type doped) and an average doping concentration of at least 1×10¹⁹ dopant atoms per cm³ (or e.g. between 1×10¹⁹ dopant atoms per cm³ and 1×10²⁰ dopant atoms per cm³), for example. The implant region may avoid or reduce avalanche breakdown in the semiconductor device 100, for example.

The semiconductor device 100 may include a plurality of laterally separated implant regions formed in the semiconductor substrate 102. The plurality of implant regions may be laterally separated from each other at the regions of the semiconductor laminar structure at which the gate structures are formed. For example, the implant regions may be laterally separated from each other along the gate structures.

The plurality of implant regions may be arranged in proximity to the (shorting) contact areas of the electrically conductive contact structure 105 with the body region 104 and the first doping region 103 arranged on the one or more sidewalls of the semiconductor laminar structure 101. For example, each implant region may be arranged in proximity to a respective contact areas of the electrically conductive contact structure 105 with the body region 104 and the first doping region 103 arranged on the one or more sidewalk of the semiconductor laminar structure 101.

Each implant region of the plurality of implant regions may be arranged between the portion of the body region 104 electrically connected to the contact areas of the electrically conductive contact structure 105 with the body region 104 and the first doping region 103 of the field effect transistor and a second doping region of the FET structure formed in the semiconductor substrate 102, for example. For example, the portion of the body region 104 electrically connected to the contact areas of the electrically conductive contact structure 105 with the body region 104 and the first doping region 103 of the field effect transistor may be arranged adjacently to the implant region, for example. For example, the implant regions may be arranged adjacent to the regions of the semiconductor laminar structure 101 which are free from gate structures, for example.

The semiconductor device 100 may include more than one FET structure. For example, each FET structure may include a first doping region 103, a body region 104 and a second doping region. The FET structure may include at least one gate structure (e.g. at least one multi-gate structure comprising the first gate structure a second gate structure), and at least one electrically conductive contact structure 105 for providing an electrical short or contact to the first doping region 103 of the FET structure and the body region 104 of the FET structure. The FET structure may further include at least one implant region arranged in proximity to a contact area of the electrically conductive contact structure 105 with the body region 104 and the first doping region 103 of the field effect transistor structure at the one or more sidewalls of the semiconductor laminar structure 101.

The plurality of FET structures may be formed from a single semiconductor laminar structure 101 due to the arrangement of the plurality of gate structures and the plurality of laterally spaced electrically conductive contact areas of the electrically conductive structure on the sidewalls of the semiconductor laminar structure 101. The plurality of FET structures formed from the single semiconductor laminar structure 101 may be part of a single FET device, for example. Each semiconductor laminar structure 101 may provide the first doping regions 103 and at least part of the body regions 104 for a plurality of FET structures of the single FET device, for example.

The semiconductor device 100 may include more than one semiconductor laminar structure 101. For example, the semiconductor laminar structure 101 may be one of a plurality of semiconductor laminar structures 101 arranged on the semiconductor substrate 102. Each of the semiconductor laminar structures 101 may be similarly structured., for example. The sidewalls of the plurality of semiconductor laminar structures 101 may be substantially parallel to each other, for example. The semiconductor device 100 may include a plurality of FET devices, and each FET device may include the plurality of FET structures formed from a single semiconductor laminar structure 101 of the plurality of semiconductor laminar structures 101, for example.

A(minimal) distance between neighboring semiconductor laminar structures 101 of the plurality of semiconductor laminar structures 101 contact structures may be at least 200 nm (or e.g. at least 500 nm, or e.g. at least 1 μm, or e.g. between 200 nm and 250 nm). A minimal distance between the neighboring semiconductor laminar structures 101 may be a shortest distance measured between a sidewall of a (first) semiconductor laminar structure 101 and a closest sidewall of a neighboring (second) semiconductor laminar structure 101, for example.

The electrically conductive contact structures 105 formed on neighboring semiconductor laminar structures 101 may be electrically connected to each other. For example, the electrically conductive contact structures 105 of neighboring semiconductor laminar structures 101 may be electrically connected to each other and/or to a first doping region contact terminal. For example, the second doping region contact structures of neighboring semiconductor laminar structures 101 may be electrically connected to each other and/or to a second doping region contact terminal.

The gate structures formed on the neighboring semiconductor laminar structures 101 may be electrically connected to each other and/or to agate terminal, for example. For example, a gate structure formed on a (first) semiconductor laminar structure 101 may be electrically connected to agate structure formed on a neighboring (second) semiconductor laminar structure 101.

The performance of MOSFET transistors may be boosted by shrinking the dimensions of the device e.g. the width/length or W/L factor). The shrinkage in dimensions may boost the device performance and allow more chips to be processed per square meter of silicon surface. Chips or transistors may become smaller with the evolution of every next generation of transistors (in accordance with Moore's Law). Smaller devices may lead to smaller active channel lengths or gate lengths, which may lead to higher current density per area or volume and higher leakage currents. With shrinkage of device dimensions, short channel effect, hot electrons, drain induced barrier lowering (DIBL) and high leakage currents may be experienced.

The various examples may relate to a gate oxide, gate dimensions, gate thickness, gate oxide properties, or gate electrode conductivity, for example. Various examples may relate to a FIN-FET transistor structure for a MOSFET transistor, for example. The device performance may be controlled or improved by fine tuning the gate oxide thickness and the type of gate oxide. With inverse proportion between the gate oxide thickness and its capacitance, decreasing the oxide thickness may lead to higher capacitance, which may affect the figure of merit (Ron*A). In addition, a continuous decrease in the gate thickness may affect the reliability of the gate for smaller thicknesses. Effective gate oxide thickness may be changed by using a different gate oxide material. Shrinking the device dimension may lead to smaller mesa with higher charge density; which may lead to leakage current or drain induced barrier lowering (DIBL), for example. This may affect the avalanche robustness of the device as charges may be swiped out of the mesa.

The various examples (e.g. FIN-FET devices) may provide a small mesa concept in the channel region to fully deplete the device & lower leakage current. In addition, they may also provide a method to realize small self-aligned contacts within metal gate process flow (without lithographic constraints), for example.

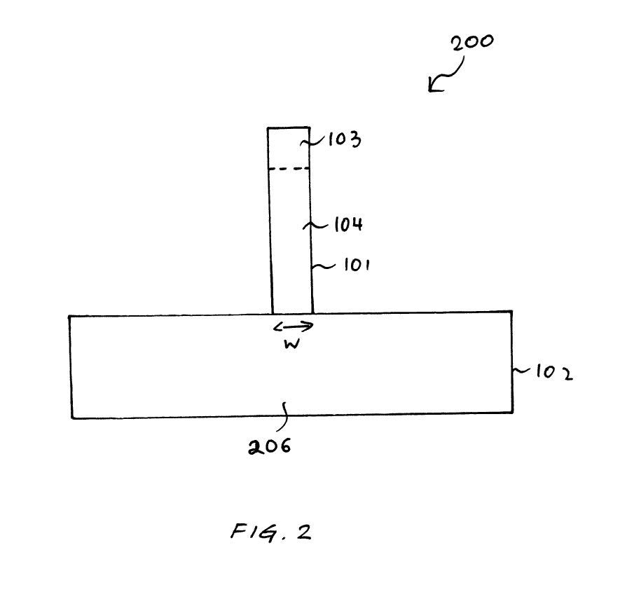

FIG. 2 shows a schematic illustration of a further semiconductor device 200 according to an embodiment.

The semiconductor device 200 comprises a semiconductor laminar structure 101 arranged on a semiconductor substrate 102. The semiconductor laminar structure 101 comprises a first doping region 103 of a field effect transistor structure and at least a part of a body region 104 of the field effect transistor structure. The body region 104 comprises a first conductivity type and the first doping region 103 comprises a second conductivity type. The semiconductor substrate 102 comprises a second doping region 206 of the field effect transistor structure. The second doping region 206 comprises a second conductivity type. A minimum lateral dimension, W, of the semiconductor laminar structure 101 is less than 200 nm.

Due to the minimum lateral dimension of the semiconductor laminar structure 101 being less than 200 nm, a small mesa in the channel region may fully deplete the device and lower leakage the current. Therefore, reliability of the semiconductor device may be improved, for example.

The semiconductor laminar structure 101 may have a minimum height of at least 300 nm, for example. For example, a minimum height of the semiconductor laminar structure 101 may lie between 300 nm and 2 μm, (or e.g. between 500 mn and 1 μm).

The semiconductor device 200 may include a plurality of semiconductor laminar structures 101. Each semiconductor laminar structure 101 may provide the first doping regions 103 and at least part of the body regions 104 for a plurality of FET structures, for example.

The semiconductor device 200 may include at least one gate structure arranged on at least one sidewall (or both sidewalk) of the semiconductor laminar structure 101 so that the semiconductor laminar structure 101 is depletable in an off-state (e.g. the semiconductor device 200 is a full-depleted or fully depletable device).

The minimum lateral dimension of the semiconductor laminar structure 101 may be located between gate structures (e.g. a multi-gate structure) formed on the sidewalls of the semiconductor laminar structure 101. Due to the minimum lateral dimension of the semiconductor laminar structure 101 being less than 200 nm, the body region of the semiconductor laminar structure 101 may be fully depleted of charges in an off state of the semiconductor device 200. For example, in an off state, the depletion zone may extend between a first sidewall of the semiconductor laminar structure 101 and a second sidewall of the semiconductor laminar structure 101 over the entire lateral dimension of the semiconductor laminar structure 101.

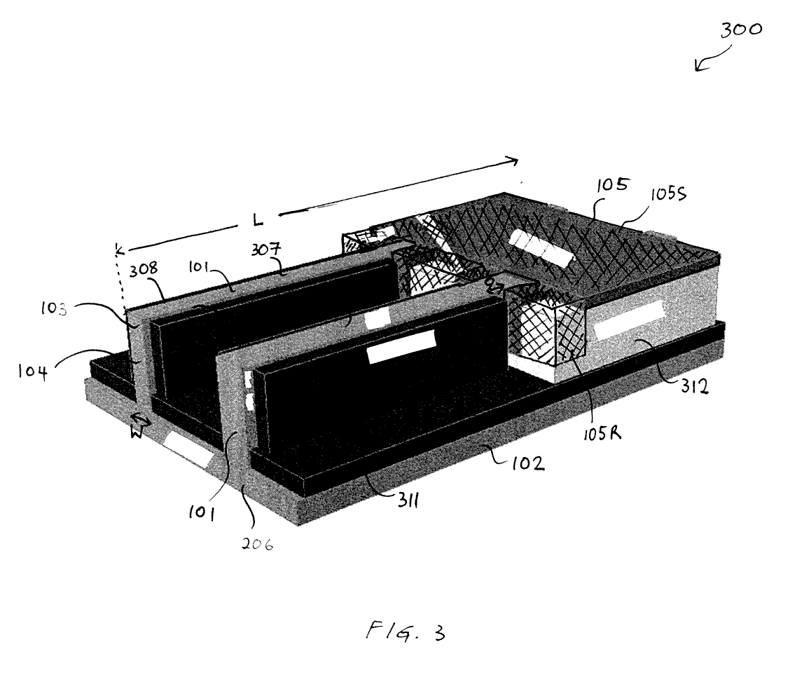

More details and aspects are mentioned in connection with the embodiments described above or below. The embodiments shown in FIG. 2 may comprise one or more optional additional features corresponding to one or more aspects mentioned in connection with the proposed concept or one or more embodiments described above (e.g. FIG. 1) or below (e.g. FIGS. 3 to 7P).

FIG. 3 shows a schematic illustration of a further semiconductor device 300 according to an embodiment. FIG. 3 shows a pictorial three-dimensional view of the semiconductor device 300 (e.g. a trench based Fin-FET), for example.

The semiconductor device 300 may be similar to the semiconductor devices described in connection with FIGS. 1 and 2.

The semiconductor laminar structure 101 may be a structure located or formed on a surface of a semiconductor substrate 102, for example. The semiconductor laminar structure 101 may be defined by the first lateral dimension (width, W) and second lateral dimension (length, L), for example. The second lateral dimension of the semiconductor laminar structure 101 may be larger than the first lateral dimension of the semiconductor laminar structure 101, for example.

The semiconductor laminar structure 101 may have a minimum height, H, of at least 300 nm, for example. For example, a minimum height of the semiconductor laminar structure 101 may lie between 300 nm and 2 μm, (or e.g. between 500 nm and 1 μm).

The top wall 307 of the semiconductor laminar structure 101 may lie between the first sidewall 308 of the semiconductor laminar structure 101 and the second sidewall 309 of the semiconductor laminar structure 101, for example.

The semiconductor laminar structure 101 may include at least part of the body region 104 of a FET structure, for example. The body region 104 of the FET structure may have a doping of a first conductivity type, for example. The doped body region 104 of the first conductivity type may be an p-type doped semiconductor region, for example. The body region 104 of the FET structure may have an average doping concentration of at least 1×10¹⁷ dopant atoms per cm³ (or e.g. between 1×10¹⁷ dopant atoms per cm³ and 1×10¹⁸ dopant atoms per cm³.

The semiconductor laminar structure 101 may further include the (first) doping region 103 of a FET structure, for example. The (first) doping region 103 of the FET structure may have a doping of a second conductivity type, for example. The (first) doping region 103 of the second conductivity type may be an n-type doped semiconductor region, for example. The (first) doping region of the FET structure may have an average doping concentration of at least 1×10¹⁷ dopant atoms per cm³ (e.g. between 1×10¹⁷ dopant atoms per cm³ and 1×10¹⁸ dopant atoms per cm³).

The electrically conductive contact structure 105 may extend along the semiconductor laminar structure 101 from a first sidewall 308 of the semiconductor laminar structure 101 to the second sidewall 309 of the semiconductor laminar structure 101. The portion of the electrically conductive contact structure 105 in contact with the (first) doping region may form a source contact structure 105S arranged on (or e.g. directly adjacent to) the top wall 307 of the semiconductor laminar structure 101. The electrically conductive contact structure 105 may have a contact area 105R with the body region 104 and the first doping region 103 (e.g. a source-body short contact) at the one or more sidewalk 308, 309 (e.g. at both sidewalls) of the semiconductor laminar structure 101.

The semiconductor device 300 may further include a gate structure 311 arranged on the sidewalls 308, 309 of the semiconductor laminar structure 101. The gate structure 311 (e.g. a polysilicon gate layer or a tungsten gate layer) may be arranged with a lateral offset, O, from a contact area 105R of the electrically conductive contact structure 105 with the body region 104 and the first doping region 103 at the one or more sidewalk of the semiconductor laminar structure 101. For example, the gate structure 311 may be separated from the contact area 105R of the electrically conductive contact structure 105 with the body region 104 and the first doping region 103 by a lateral offset of between 30 nm and 100 nm. The gate structure 311 may be arranged laterally between neighboring contact areas 105R of the electrically conductive contact structure 105 with the body region 104 and the first doping region 103 of the field effect transistor structure. The semiconductor device 300 may further include agate oxide layer arranged between the gate structure 311 and the sidewalk 308, 309 of the semiconductor laminar structure 101, for example.

The semiconductor device 300 may include electrically insulating material 312 arranged on the sidewalls 308, 309 of the semiconductor laminar structure 101, for example. For example, the gate structure 311 may be separated or electrically insulated from adjacent contact areas 105R of the electrically conductive contact structure 105 with the body region 104 and the first doping region 103 of the field effect transistor by a portion of the electrically insulating material 312 located on the sidewalk 308, 309 between the gate structures 311 and the adjacent (or neighboring) contact areas 105R, for example. A (further) portion of the electrically insulating material 312 may be arranged on the one or more sidewalls 308, 309 (e.g. on the sidewalls) of the semiconductor laminar structure 101 between the gate structure 311 and the portion of the electrically conductive contact structure 105 in contact with the first doping region 103 of the field effect transistor structure on a top wall 307 of the semiconductor laminar structure 101, for example. The electrically insulating material 312 may be silicon dioxide, high-density plasma chemical vapor deposition (HDP) oxide, and/or borophosphosilicate glass (BPSG), for example.

The second doping region 206 of the FET structure may be located in the semiconductor substrate 102, for example. The second doping region 206 of the FET structure may have a doping of a second conductivity type (e. n-type doping) and an average doping concentration of at least 1×10¹⁷ dopant atoms per cm³, (or e.g. between 1×10¹⁷ dopant atoms per cm³ and 1×10¹⁸ dopant atoms per cm³), for example. The second doping region may be a drain region of a MOSFET structure or a drift region of an IGBT structure, for example.

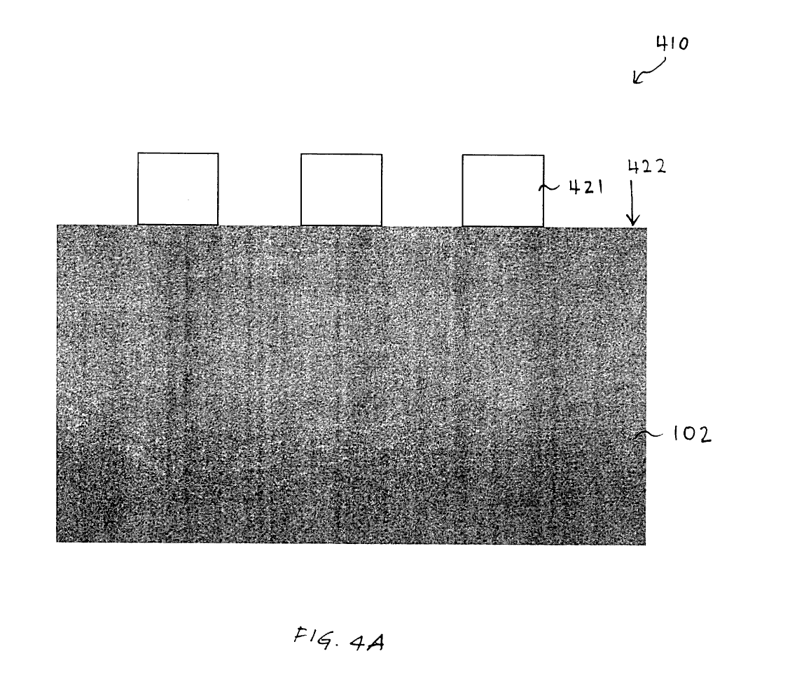

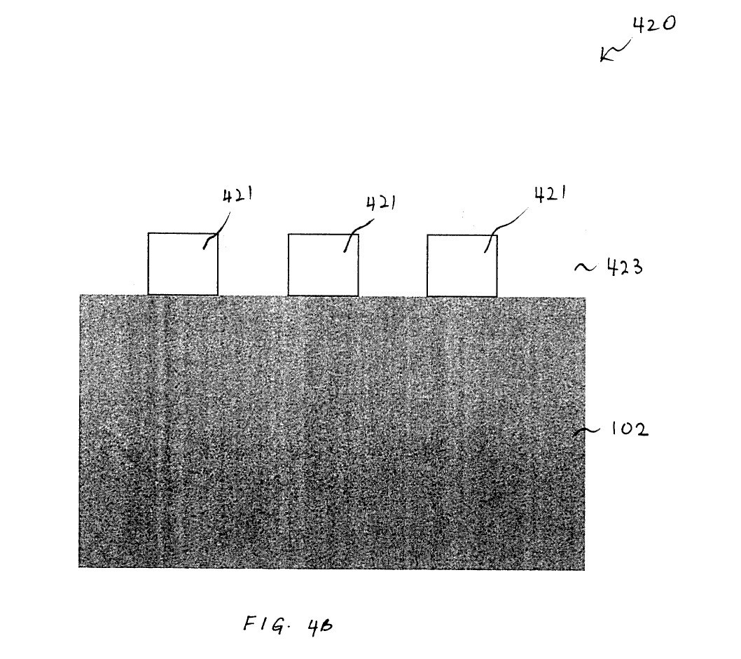

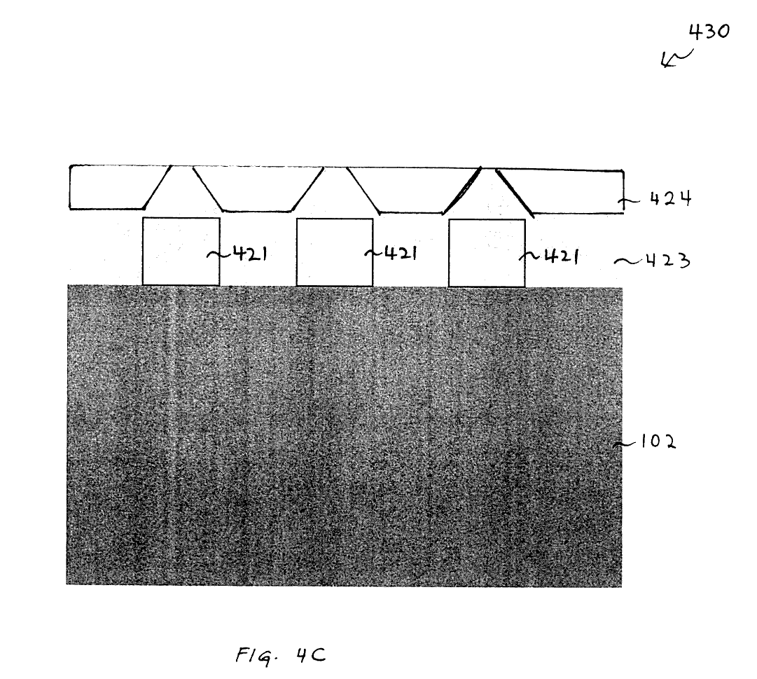

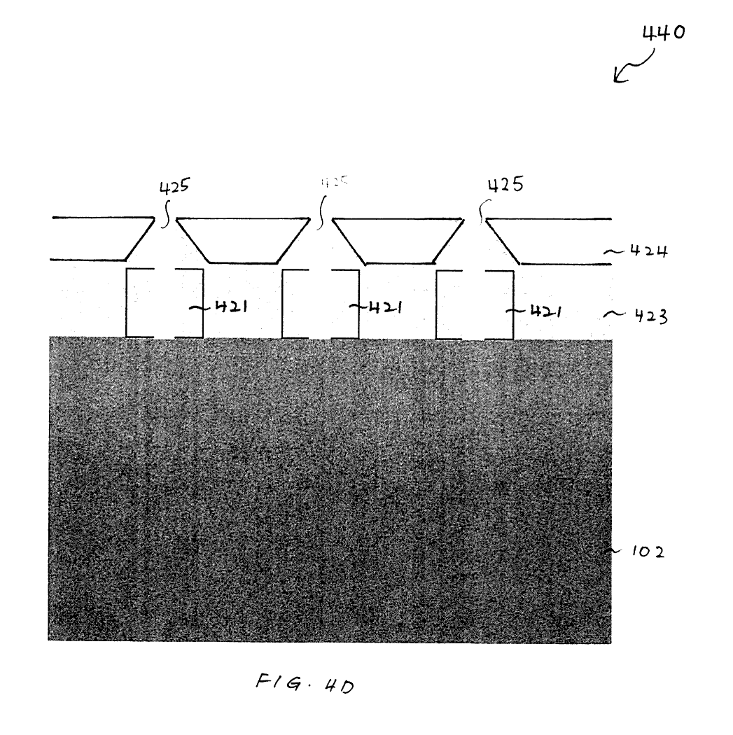

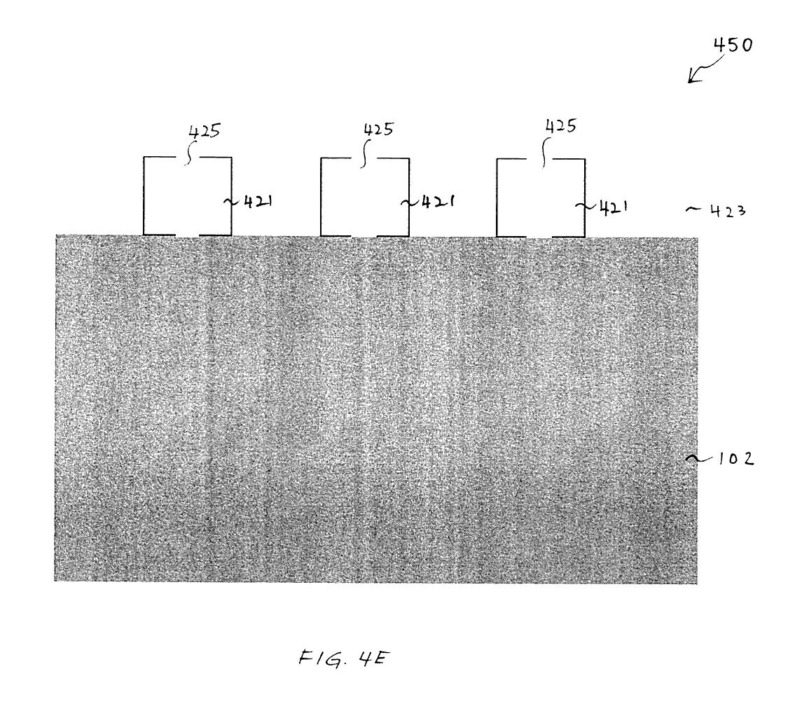

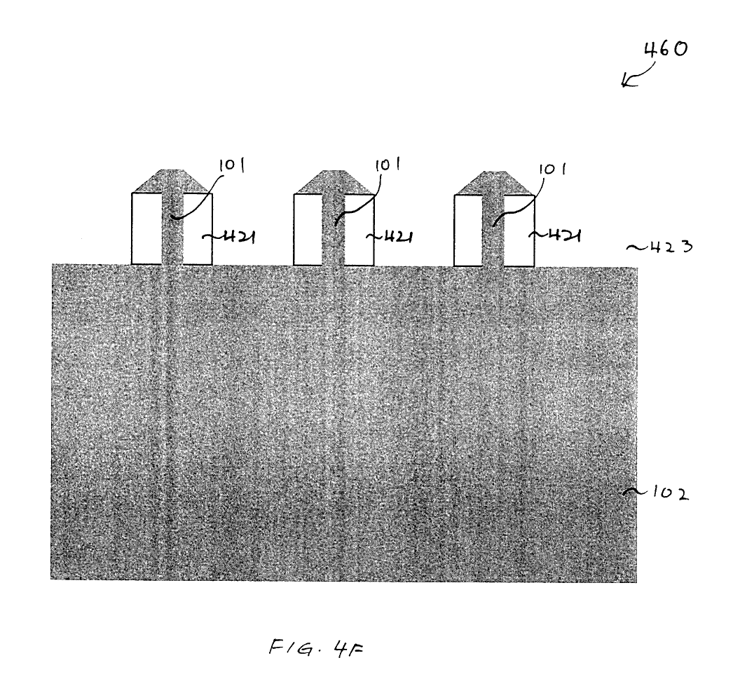

More details and aspects are mentioned in connection with the embodiments described above or below. The embodiments shown in FIG. 3 may comprise one or more optional additional features corresponding to one or more aspects mentioned in connection with the proposed concept or one or more embodiments described above (e.g. FIGS. 1 to 2) or below (e.g. FIGS. 4A to 7P).

FIGS. 4A to 4F show schematic illustrations (410 to 460) of a method for forming at least one semiconductor laminar structure 101 according to an embodiment. For example, the method may be a process flow for forming a FIN-FET using vertically grown Si-nano pillar or Si-nano trenches.

FIG. 4A shows a schematic illustration 410 of hard mask structures 421 formed on a surface 422 of a semiconductor substrate 102.

The method may include forming a hard mask layer over a main or first surface 422 of a semiconductor substrate 102. The material of the hard mask layer may be silicon dioxide, for example. The method may include forming the silicon dioxide layer by oven oxidation of silicon, for example. Lithography and subsequent etching processes may be used to structure or pattern the hard mask layer so that hard mask structures 421 remain on the first surface of the semiconductor substrate 102, for example.

FIG. 4B shows a schematic illustration 420 of a high-density plasma chemical vapor deposition (HDP) oxide layer 423 formed over the hard mask structures 421.

The method may further include forming the high-density plasma chemical vapor deposition (HDP) oxide layer 423 over the patterned hard mask structures 421 in a poly lens concept, for example. The HDP oxide layer 423 may be formed on the hard mask structures 421 and on exposed regions of the semiconductor substrate 102 which are free from (or not covered by) the hard mask material, for example. Regions of the HDP oxide layer 423 formed on the hard mask structures may have a pyramidal or dome shaped topography, for example.

FIG. 4C shows a schematic illustration 430 of a polysilicon layer 424 formed over the HDP oxide layer.

The method may further include forming a polysilicon layer 424 or material over the HDP oxide layer 423. The method may further include polishing a surface of the polysilicon layer 424 or removing polysilicon from a surface of the polysilicon layer 424 to produce an even surface layer. The polishing may be carried out so that at least part of the HDP oxide layer 423 formed on the hard mask structures 421 is exposed and/or removed at the polished surface. The polishing may be carried out by chemical mechanical polishing (CMP), for example.

FIG. 4D shows a schematic illustration 440 of trench structures 425 formed on the semiconductor substrate 102.

The method may further include etching the portions of the HDP oxide layer 423 exposed at the polished surface. The etching carried out may be an oxide etching process to form the trench structure 425, each trench structure 425 extending through the exposed HDP oxide layer 423 and the hard mask structure 421 covered by the HDP oxide layer 423. The width of the trench structure 425 (and thus the eventually width of the semiconductor laminar structure) may be easily tuned in the range of between 10 nm to 100 nm by varying the HDP oxide layer thickness, for example. The method may further include providing chemical mechanical polishing (CMP) at the surface of the polysilicon layer 424 to remove the polysilicon layer 424 and contours formed by the polysilicon layer 424 and the HDP oxide layer 423.

FIG. 4E shows a schematic illustration 450 of a polished surface of the HDP oxide layer 423.

The CMP may be carried out until the polysilicon layer is removed and part of the hard mask structure 421 is exposed at a surface of the HDP oxide layer 423, for example. For example, the CMP may be carried out so that a flat or even surface comprising the HDP oxide layer 423 and the hard mask structure 421 is formed.

FIG. 4F shows a schematic illustration 460 of semiconductor laminar structures 101 being formed in the trench structures.

The method may further include selectively growing silicon laminar structures 101 (e.g. by selective silicon epitaxy) in the trench structures, for example. The epitaxial silicon grown in the trench structure may fill the trench structures, for example. Overhanging or excess epitaxial silicon may be formed in regions on the hard mask structures outside the trench structures, for example. Optionally or alternatively, the method may include forming the semiconductor laminar structures by etching trenches extending into the semiconductor substrate 102. Optionally or alternatively, other suitable processes for forming semiconductor laminar structures (e.g. fins) may be used for forming the semiconductor laminar structures 101, for example.

The method may further include etching or removing excess epitaxial silicon outside the trench structures, for example. The removal of the excess epitaxial silicon may be carried out by etching or CMP, for example. The epitaxial silicon grown in the trench structure may form the eventual semiconductor laminar structures 101 arranged on the surface of the semiconductor substrate 102, for example.

The method may further include removing the hard mask structures 421 and the HDP oxide layer 423 remaining on the semiconductor substrate 102 surface so that a plurality of parallel, laterally separated semiconductor laminar structures 101 are arranged on the surface of the semiconductor substrate 102, for example.

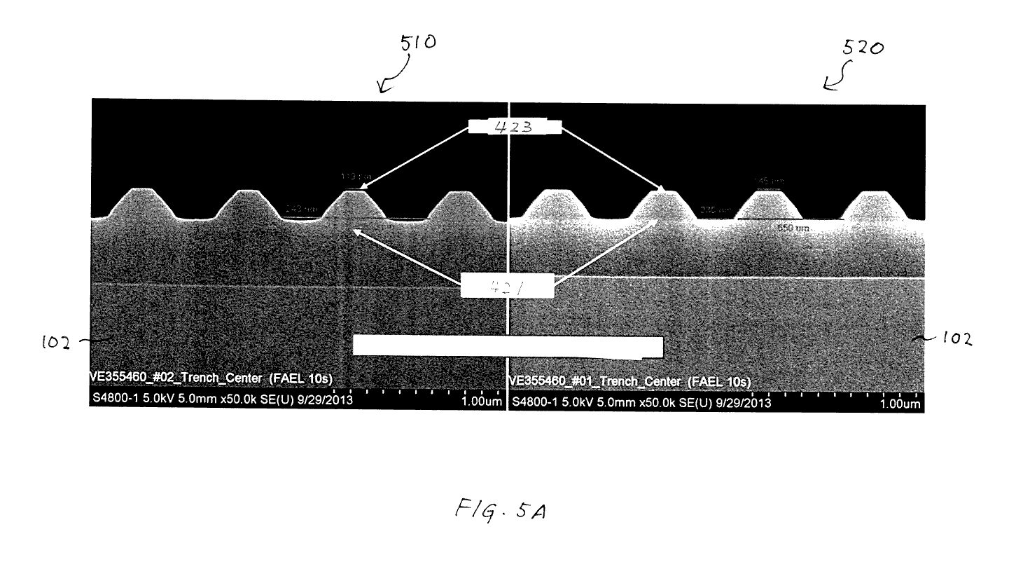

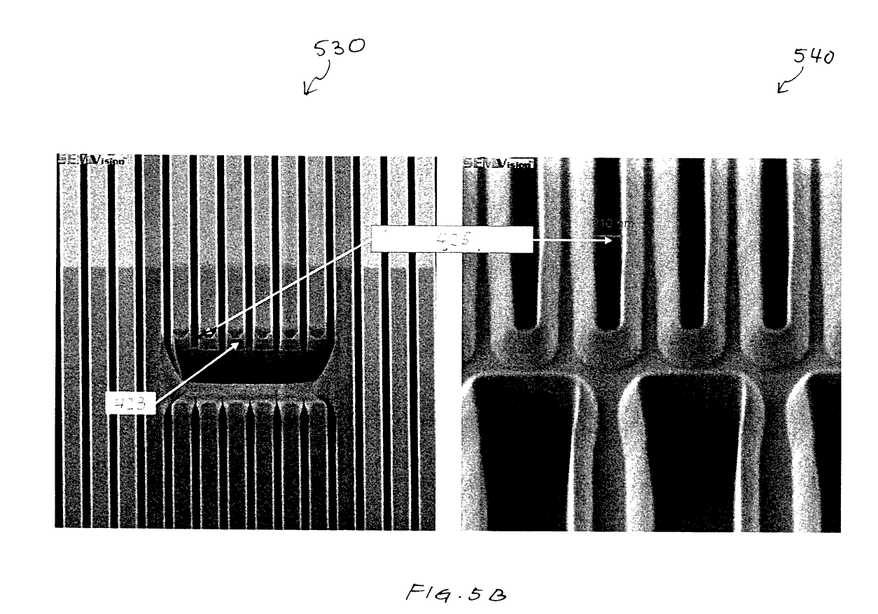

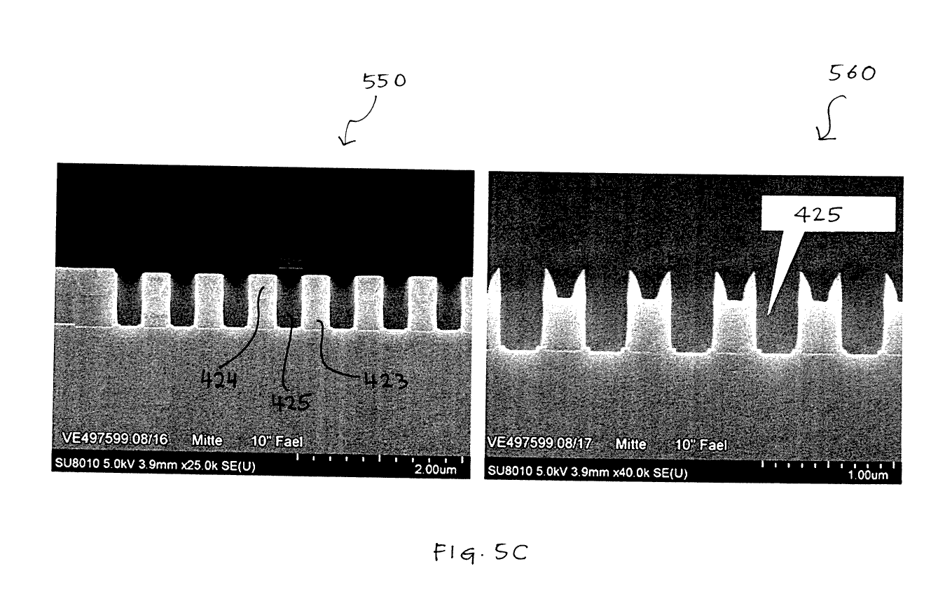

More details and aspects are mentioned in connection with the embodiments described above or below. The embodiments shown in FIGS. 4A to 4F may comprise one or more optional additional features corresponding to one or more aspects mentioned in connection with the proposed concept or one or more embodiments described above FIGS. 1 to 3) or below (e.g. FIGS. 5A to 7P).

FIG. 5A shows micrographs 510, 520 of part of the process for forming the semiconductor laminar structures 101. For example, the micrographs 510, 520 show a cross-sectional view of the semiconductor substrate 102, the hard mask structures 421 (silicon dioxide) and the HDP oxide layer 423 after the HDP oxide deposition and before etching the trench structures as described in connection with FIGS. 4A to 4F.

In the micrograph 510, a minimal (or smallest) lateral dimension of the pyramidal region of the HDP oxide layer 423 formed on the hard mask structure 421 may be about 119 nm, for example. A distance between a first pyramidal region and a consecutive third pyramidal region of the HDP oxide layer may be about 243 nm, for example.

In the micrograph 520, a minimal (or smallest) lateral dimension of the pyramidal region of the HDP oxide layer formed on the hard mask structure may be 145 nm. A distance between a first pyramidal region and a consecutive second pyramidal region of the HDP oxide layer may be about 230 nm, for example. A distance between a respective first side of a first hard mask structure and a first side of a consecutive second hard mask structure may be about 650 nm, for example.

A lateral dimension (or e.g. a minimal lateral dimension) of the semiconductor laminar structures to be formed may be based on the minimal (or smallest) lateral dimension of the pyramidal regions formed by the process described in connection with FIGS. 4A to 4F and FIG. 5A.

FIG. 5B shows micrographs 530, 540 of part of the process for forming the semiconductor laminar structures 101.

The micrograph 530 shows a top view of the trench structures 425 formed in the HDP oxide layer after the oxide etching, for example. A width of the trench structures 425 may be about 140 nm, for example.

The micrograph 540 shows a top view of the trench structures 425 formed in the HDP oxide layer 423 after the oxide etching and polysilicon etching. A width of the trench structures 425 may be about 210 nm, for example.

Two (or more) different sizes of the trench structures 425 may be obtained. Therefore, two (or more) different sizes of the fin or laminar structures may be tuned using the HDP process, for example.

FIG. 5C shows micrographs 550, 560 of part of the process for forming the semiconductor laminar structures 101.

The micrograph 550 shows a cross-sectional side view of the trench structures formed in the HDP silicon oxide layer after the oxide etching using the poly lens, for example. For example, polysilicon may be located on the hard mask structures. A trench structure formed in the hard mask structure may have a lateral dimension of 310 nm, for example.

The micrograph 560 shows a cross-sectional side view of the trench structures 425 formed in the HDP oxide layer after the removal of polysilicon, and the trench structures ready for silicon fin growth, for example. Areas (or trench structures) for the elective growth of the semiconductor laminar structures 101 (e.g. the Si Fin) using epitaxy are located between neighboring hard mask structures, for example. The fin may be grown with the body dose to avoid implantation afterwards, for example.

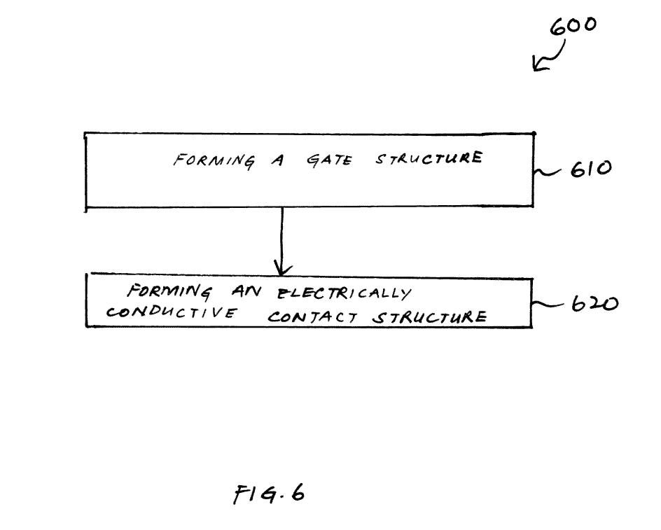

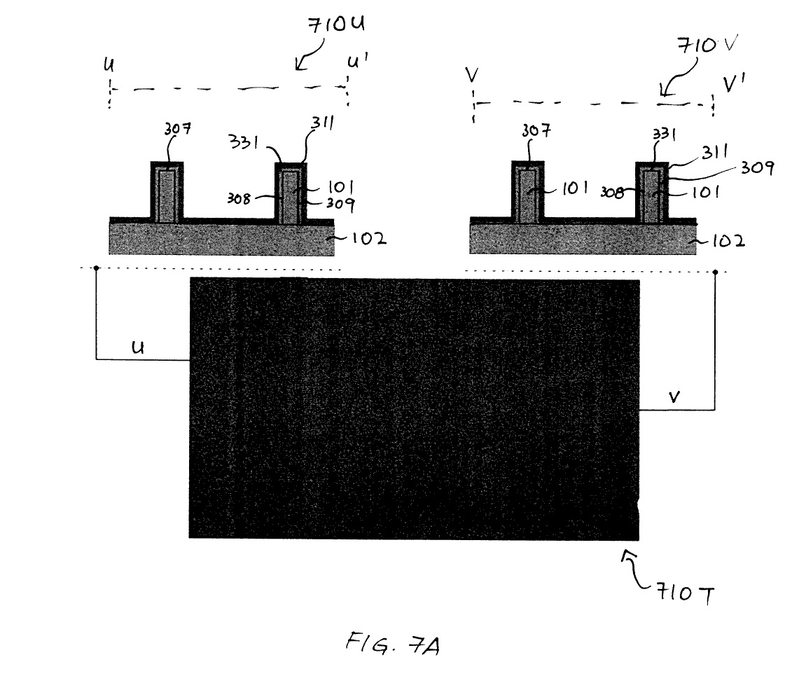

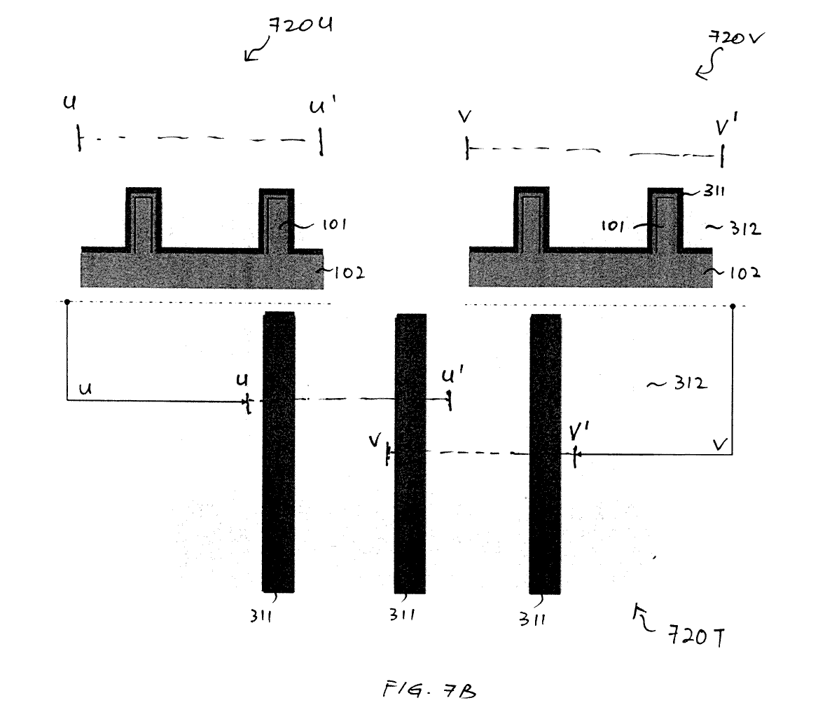

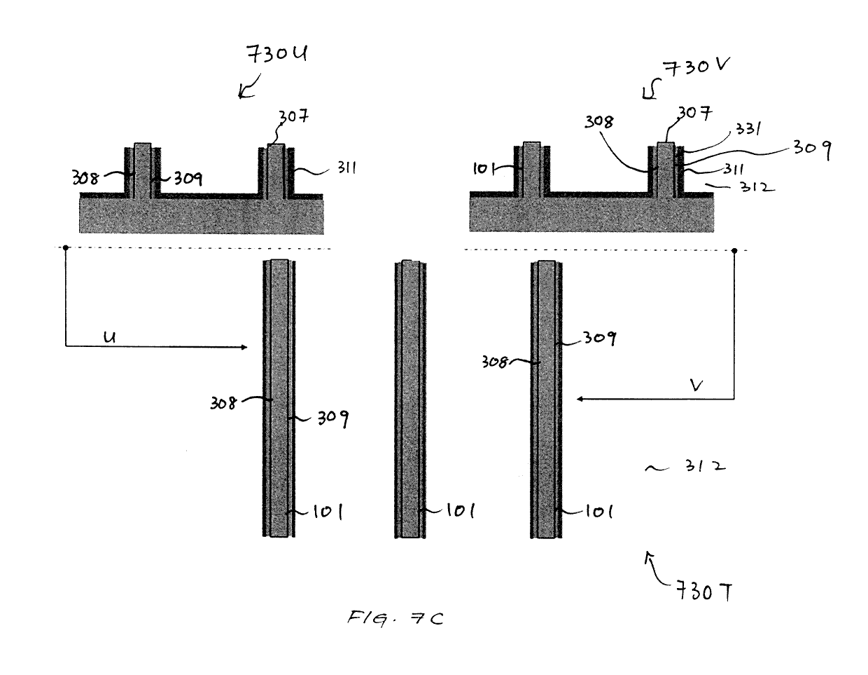

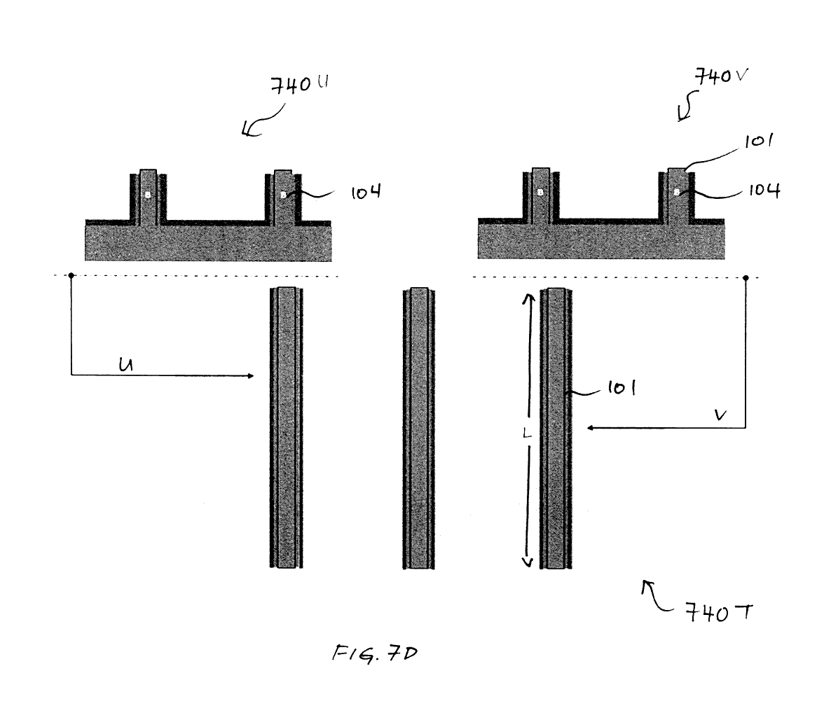

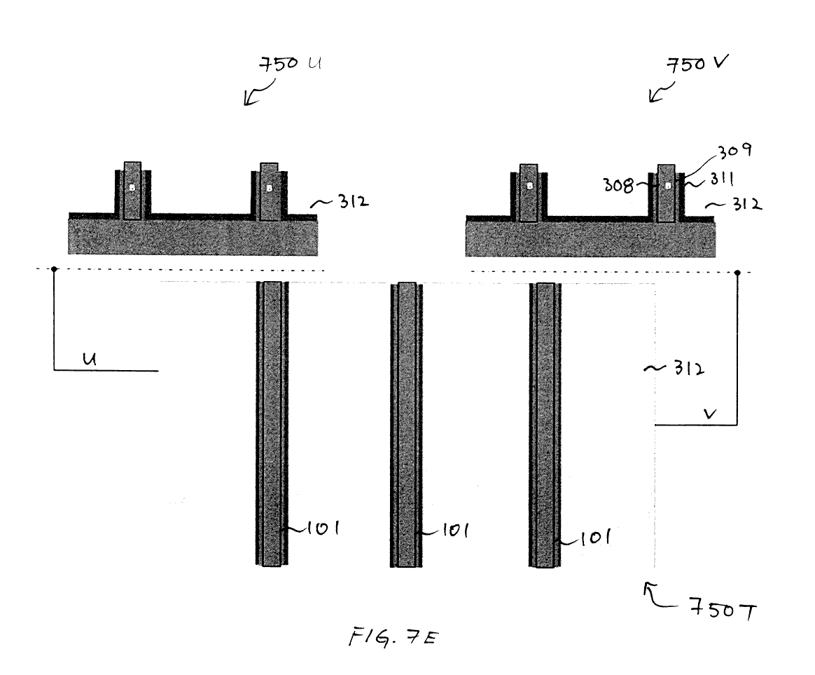

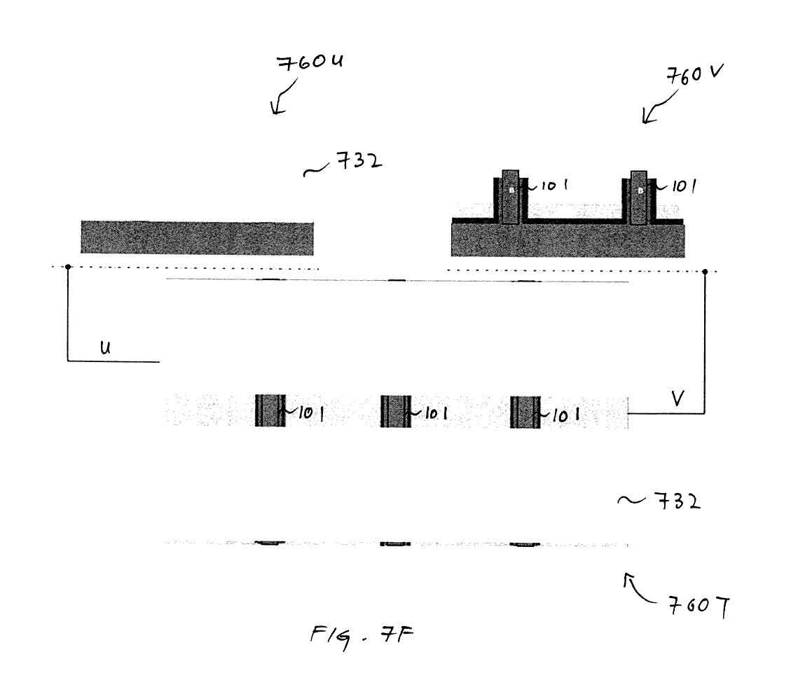

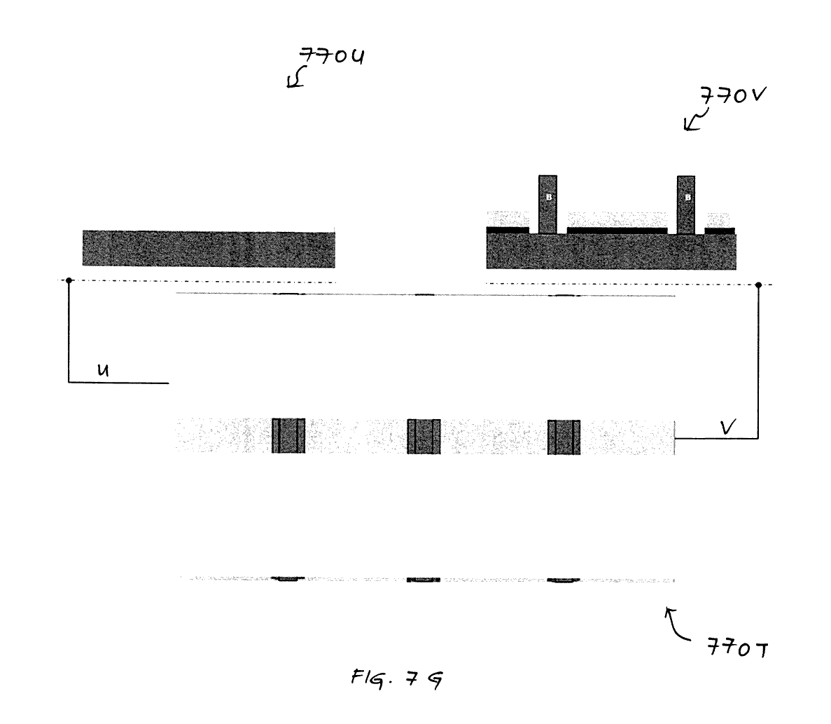

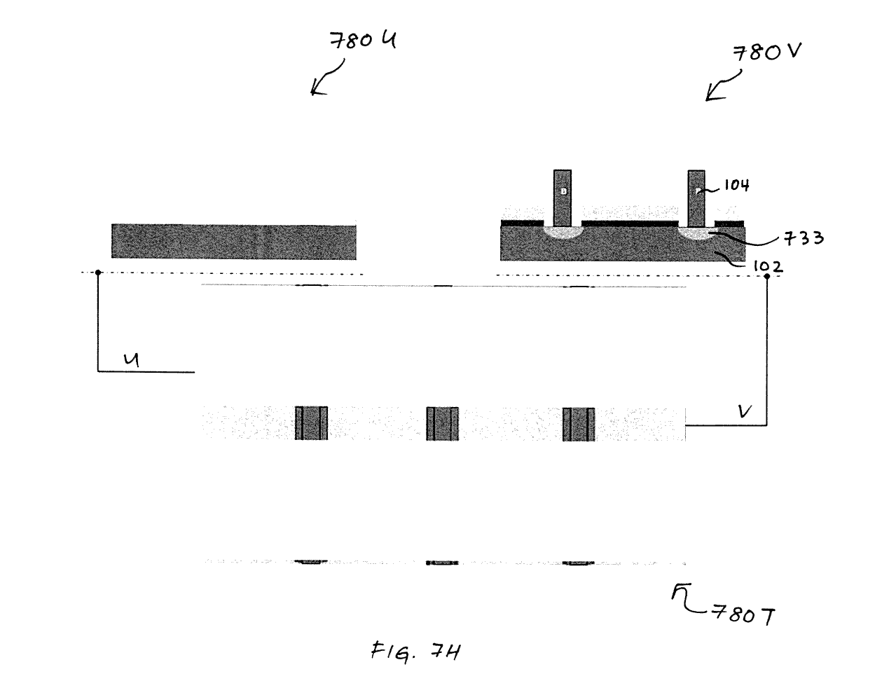

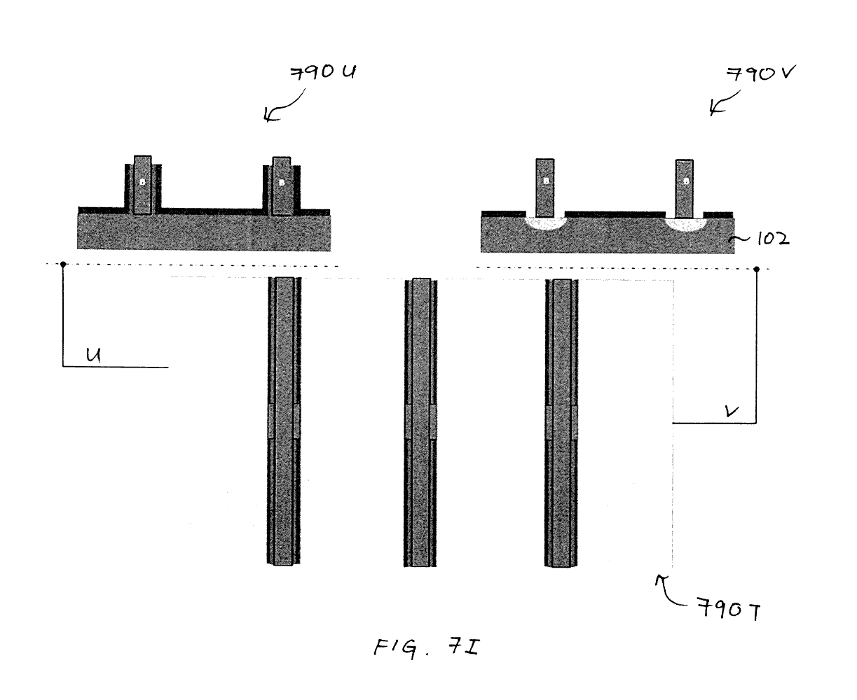

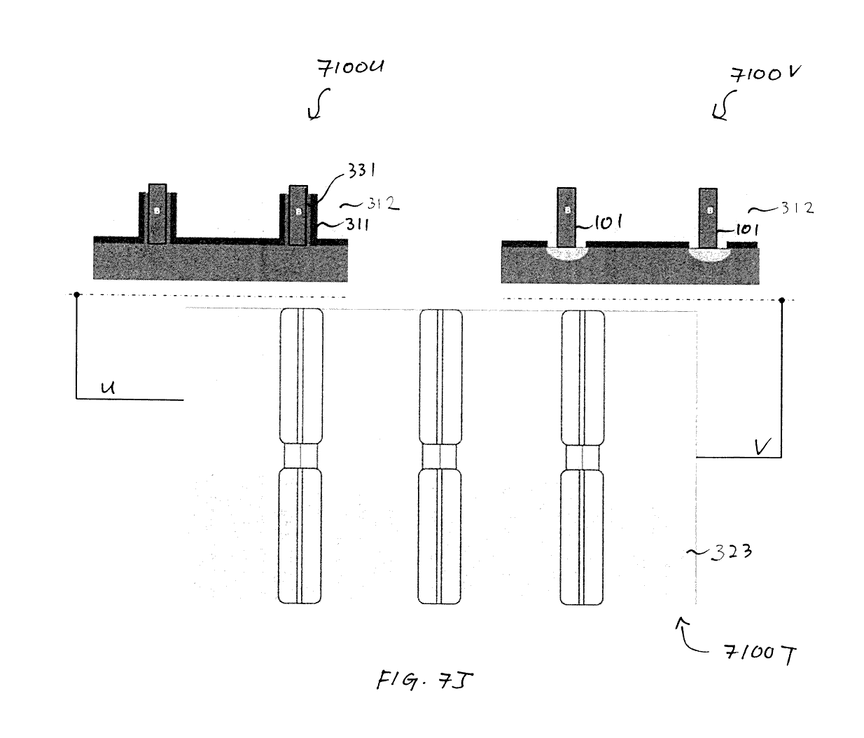

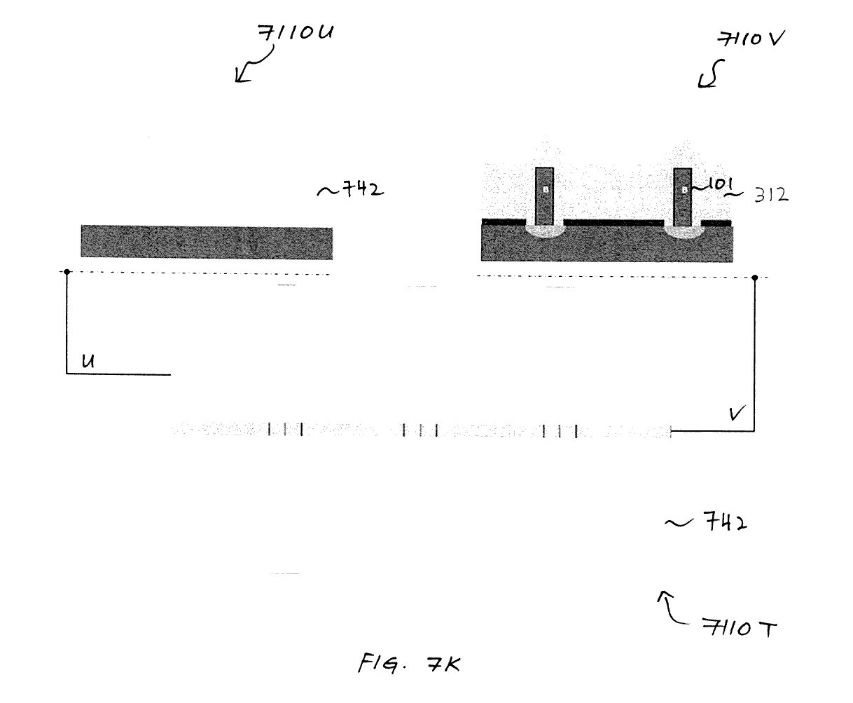

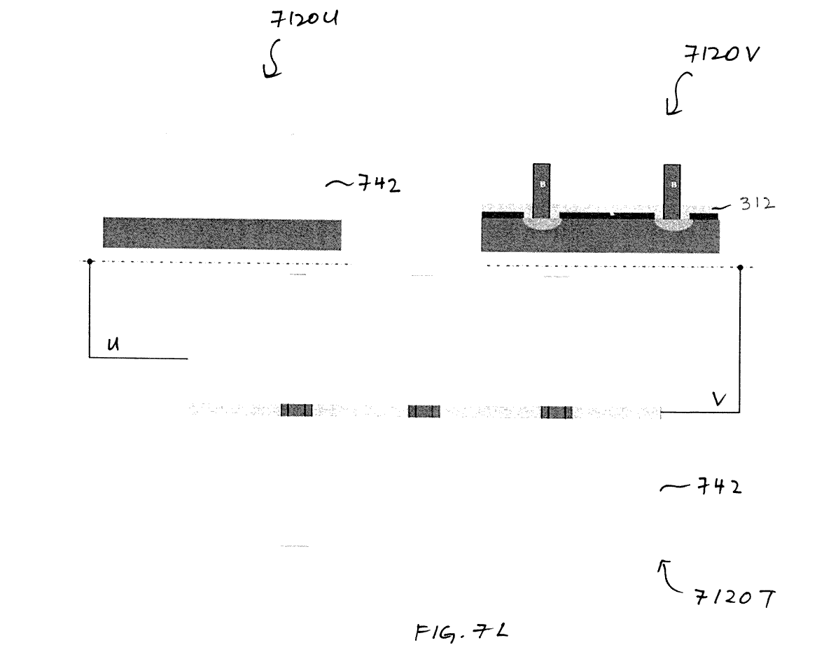

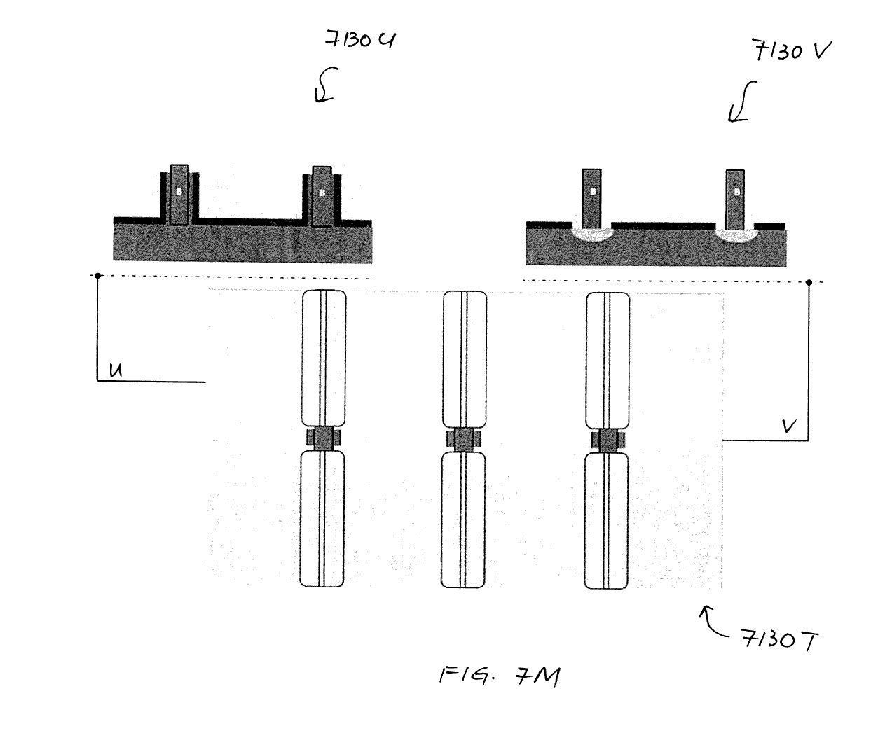

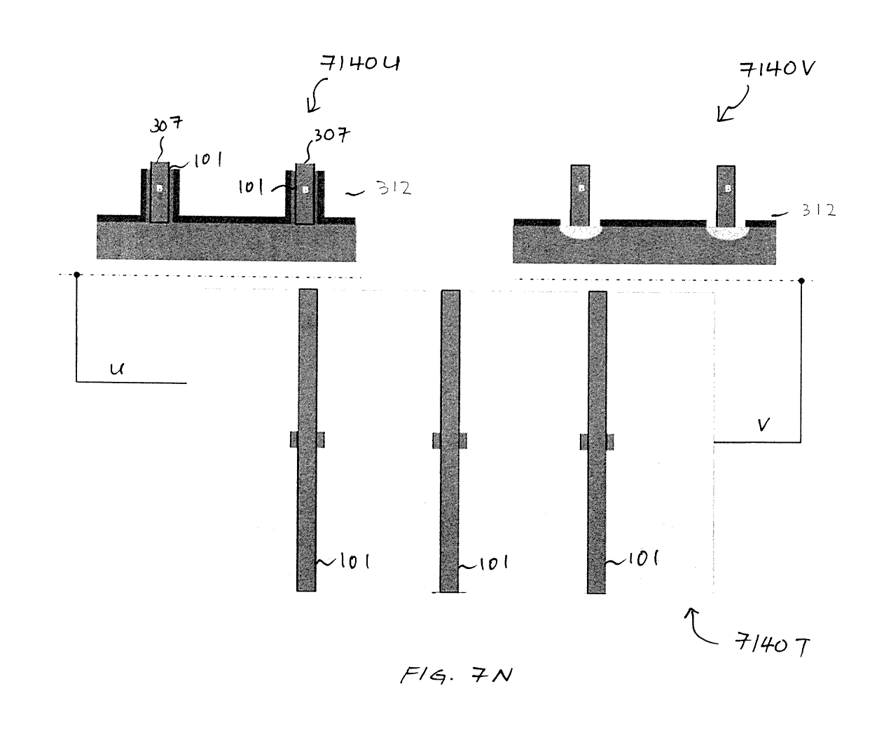

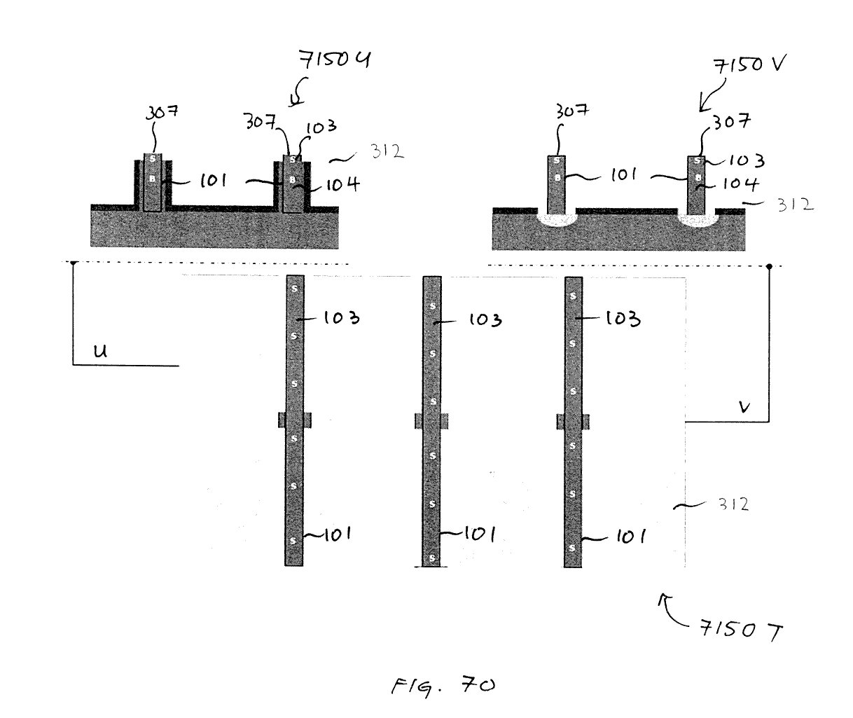

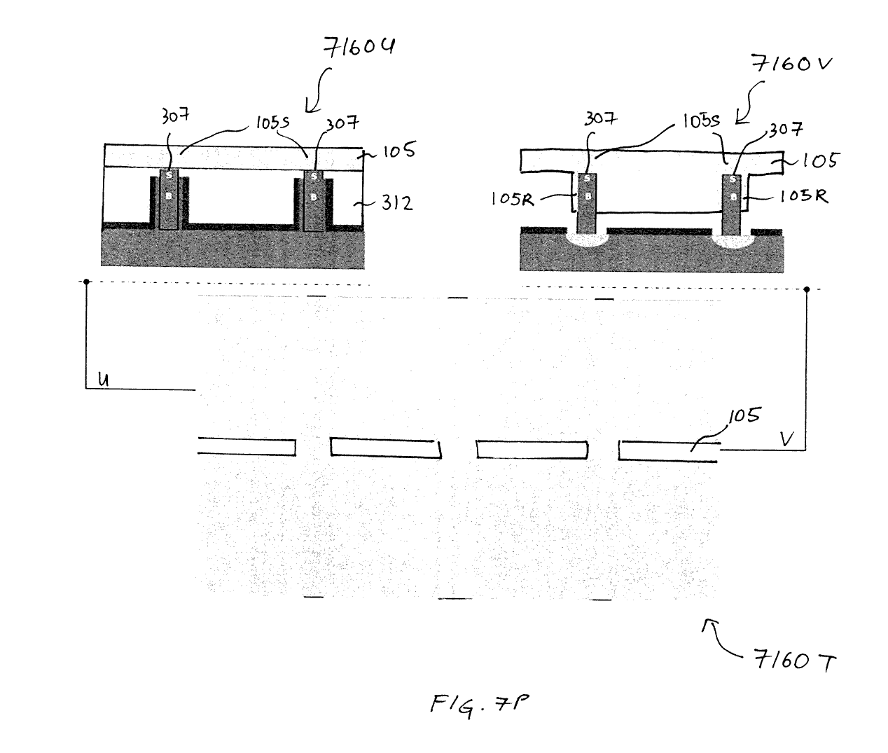

More details and aspects are mentioned in connection with the embodiments described above or below. The embodiments shown in FIGS. 5A to 5C may comprise one or more optional additional features corresponding to one or more aspects mentioned in connection with the proposed concept or one or more embodiments described above (e.g. FIGS. 1 to 4F) or below (e.g. FIGS. 6 to 7P).

FIG. 6 shows a flow chart of a method 600 for forming a semiconductor device according to an embodiment.

The method 600 comprises forming 610 a gate structure of a field effect transistor structure on at least one sidewall of the semiconductor laminar structure.

The method 600 further comprises forming 620 an electrically conductive contact structure in contact with a doping region of the field effect transistor structure in the semiconductor laminar structure at the sidewall of the semiconductor laminar structure.

Due to the forming of an electrically conductive contact structure and a gate structure on the one or more sidewalk of the semiconductor laminar structure, field effect transistor structures which are more reliable may be provided. For example, the FET transistors may be fully depleted. Furthermore, a plurality of devices may be easily formed from a single semiconductor laminar structure. Thus, FET structures may be more efficiently produced, for example.

The doping region may include or be a source region or drain region of a MOSFET structure or an emitter region or collector region of an IGBT structure. Additionally, or optionally, the doping region may be or include a body of a MOSFET structure or IGBT structure, for example.

More details and aspects are mentioned in connection with the embodiments described above or below. The embodiments shown in FIG. 6 may comprise one or more optional additional features corresponding to one or more aspects mentioned in connection with the proposed concept or one or more embodiments described above (e.g. FIGS. 1 to 5C) or below (e.g. FIGS. 7A to 7P).

FIGS. 7A to 7P show schematic illustrations of a method for forming a semiconductor device comprising a plurality of FET structures according to an embodiment.

FIGS. 7A to 7P show a plurality of semiconductor laminar structures 101 arranged on a first surface of a semiconductor substrate 102. The semiconductor laminar structures 101 may be similar to the semiconductor laminar structures 101 described in connection with FIGS. 1 to 6, for example. The semiconductor substrate 102 may include at least one doping region. At least one doping region of the semiconductor substrate 102 may include a drain region of a MOSFET structure or a drift region of an IGBT structure, for example. Optionally, at least one (further) doping region of the semiconductor substrate 102 may include a collector region of an IGBT structure, for example.

FIGS. 7A to 7P each show a respective top view illustration (T) of semiconductor laminar structures 101 formed on a semiconductor substrate 102 a cross-sectional view (along the line U-U′) at a region U of the semiconductor laminar structure 101, and a cross-sectional view (along the line V-V′) at a region V of the semiconductor laminar structure 101.

Region V of the semiconductor laminar structure 101 may represent a region of the semiconductor laminar structure 101 at which a contact area of an electrically conductive contact structure to the body region and the first doping region of the field effect transistor (providing a source-body shorting contact area) is to be formed at (or on) the sidewalls of the semiconductor laminar structure 101, for example.

Region U of the semiconductor laminar structure 101 may represent a region of the semiconductor laminar structure 101 which is free from the (shorting) contact areas (source-body shorting contact areas) of the electrically conductive contact structure with the body region and the first doping region 103 of the field effect transistor, for example.

FIG. 7A shows schematic illustrations 710T, 710U, 710V of the forming of a gate oxide layer 331 and an electrically conductive gate structure 311 on the semiconductor laminar structures 101.

The method may include forming the conformal gate oxide layer 331 and subsequently the conformal electrically conductive gate layer structure 311 on the sidewall surfaces 308, 309 and top wall surfaces 307 of the semiconductor laminar structures 101 and/or on the exposed surface regions of the semiconductor substrate 102 between neighboring semiconductor laminar structures 101, for example. The electrically conductive gate structure 311 may be formed on the gate oxide layer 331, for example. For example, the gate oxide layer 331 and the electrically conductive gate structure 331 may be formed conformally on the surfaces (e.g. the sidewall surfaces 308, 309 and the top wall surfaces 307) of the semiconductor laminar structures 101.

FIG. 7B shows schematic illustrations 720T, 720U, 720V of a subsequent deposition of electrically insulating material 312 and an etch back process.

The method may include depositing the electrically insulating material 312 (e.g. a silicon dioxide layer) on the electrically conductive gate structure after forming the gate structure. The electrically insulating material 312 may cover (or embed or encapsulate) the semiconductor laminar structures 101, the electrically conductive gate structure 311 and the gate oxide layer, for example. The electrically insulating material may be formed in the regions between neighboring semiconductor laminar structures 101, for example. The electrically insulating material 312 may fill the gaps between neighboring semiconductor laminar structures 101, for example.

The method may further include etching back the electrically insulating material 312 embedding the semiconductor laminar structures 101 so that a portion of the electrically conductive gate structure 311 formed on the top portions of the semiconductor laminar structures 101 may be exposed, for example. The etching of the electrically insulating material 312 may be carried out so that portions of the electrically insulating material 312 may remain between the neighboring semiconductor laminar structures 101, for example. For example, the etching of the electrically insulating material 312 may be carried out so that a height of the remaining electrically insulating material 312 measured from the semiconductor substrate 102 surface may be smaller than a height of the semiconductor laminar structure 101 (not including the thickness of the electrically conductive gate structure and the gate oxide layer).

FIG. 7C shows schematic illustrations 730T, 730U, 730V of a subsequent etching of the exposed portions of the electrically conductive gate structure and the gate oxide layer at the top portions and at exposed sidewall regions of the semiconductor laminar structures 101.

The method may include removing the electrically conductive gate structure 311 (using agate polysilicon etch) and the gate oxide layer 331 (using agate oxide etch) located on a top wall 307 of the semiconductor laminar structure 101, for example. The method may further include removing portions of the electrically conductive gate structure 311 and portions of the gate oxide layer 331 from regions of the sidewall 308, 309 of the semiconductor laminar structure 101 which were not covered by the electrically insulating material 312, for example.

After the etching, the top walls 307 of the semiconductor laminar structures 101 and the regions of the sidewall directly adjacent to the top walls 307 of the semiconductor laminar structure 101 may be exposed. For example, they may be free from (or not covered by) the electrically conductive gate structure and the gate oxide layer, for example. A portion of the sidewall regions that are free from (or not covered by) the electrically conductive gate structure and the gate oxide layer may lie between 10% and 306% of the height of the semiconductor laminar structure 101, for example. Remaining portions of the sidewalls 308, 309 of the semiconductor laminar structure 101 may remain covered by the electrically conductive gate structure 311 and the gate oxide layer 331, for example.

FIG. 7D shows schematic illustrations 740T, 740U, 740V of an implantation of dopant atoms to form the body region 104 in the semiconductor laminar structures 101, for example.

The implantation of dopant atoms (e.g. acceptor) atoms may be optionally carried out if the doping of the body region 104 was not carried out during the epitaxial growth of the semiconductor laminar structures 101, for example.

The implantation may include incorporating boron (B) or aluminum (Al) atoms into the semiconductor laminar structures 101, for example. The incorporated dopant atoms may form a laterally extending body region 104 in each semiconductor laminar structure 101, for example. The laterally extending body region 104 may extend along the length, L, of the semiconductor laminar structures 101, for example. The laterally extending body region 104 may provide the body regions 104 of a plurality of transistor structures of the semiconductor device, for example.

The part of the body region 104 of the FET structure formed in the semiconductor laminar structure 101 may be implanted at a doping dosage of at least 3×10¹² ions per cm² e.g. between 3×10¹² ions per cm² and 4×10¹³ ions per cm²), for example.

FIG. 7E shows schematic illustrations 750T, 750U, 750V of an etching back of the electrically insulating material 312 located between neighboring semiconductor laminar structures 101, for example. The etching back of the electrically insulating material (e.g. an oxide etch back process) may lead to portions of the electrically conductive gate structure 311 formed on the sidewalls 308, 309 of the semiconductor laminar structures 101 being exposed, for example.

The etching of the electrically insulating material 312 may be carried out so that portions of the electrically insulating material 312 may remain between the neighboring semiconductor laminar structures 101, for example. For example, the remaining electrically insulating material 312 may laterally surround the bottom portions of the semiconductor laminar structure 101 adjacent to the semiconductor substrate 102. A height of the bottom portion of the semiconductor laminar structure 101 covered by the remaining electrically insulating material may be between 10% and 15% of the height of the semiconductor laminar structure 101, for example.

FIG. 7F shows schematic illustrations 760T, 760U, 760V of a lithography process to expose regions (e.g. regions V) of the semiconductor laminar structures 101 at which the contact areas of the electrically conductive contact structure with the body region and the first doping region of the field effect transistor structure are to be formed. Other regions of the semiconductor laminar structures 101 (e.g. regions U) which are to be free from the shorting contact areas may be covered by a lithography mask material (e.g. a photoresist), for example.

The top view 760T shows neighboring exposed regions of the neighboring semiconductor laminar structures 101 at regions V of the semiconductor laminar structure 101 at which shorting contact areas of the electrically conductive contact structure 105 are to be formed, for example.

The cross-sectional view 760V shows the exposed regions of the semiconductor laminar structures 101 at which the shorting contact areas of the electricallyconductive contact structure 105 are to be formed.

The cross-sectional view 760U shows the other regions (U) of the semiconductor laminar structures 101 covered with a lithography mask material 732.

FIG. 7G shows schematic illustrations 770T, 770U, 770V of an etching of the electrically conductive gate structure and the gate oxide layer at the exposed regions (V) of the semiconductor laminar structures 101.

After the partial etch of gate metal and the gate oxide (in FIG. 7E), using the lithography mask from the small area (e.g. region V) of the trenches, the gate oxide & gate metal may be etched away.

As shown in cross-sectional view 770V of the exposed regions (V), the electrically conductive gate structure and the gate oxide layer may be removed in the regions (V) of the semiconductor laminar structure 101 at which shorting contact areas of the electrically conductive contact structure 105 are to be formed, for example. The semiconductor laminar structure 101 may thus be free from any additional layers in the regions (V) of the semiconductor laminar structure 101 at which the shorting contact areas of the electrically conductive contact structure 105, for example.

FIG. 7H shows schematic illustrations 780T, 780U, 780V of the forming of the implant region 733. The implantation may be carried out by incorporating dopant atoms into the semiconductor substrate 102 at the exposed regions of the semiconductor substrate 102. The implantation of the p+ implant region may be carried out a dosage of at least 1×10¹⁴ ions per cm², (or e.g. between 1×10 ¹⁴ ions per cm²and 1×10¹⁵ ions per cm²), for example.

The exposed regions of the semiconductor substrate 102 may be located adjacent to the regions of the semiconductor laminar structure 101 from which the electrically conductive gate structure and the gate oxide layer were removed. Diffusion may be carried out so that the implant region 733 may be formed between the part of the body region 104 located in the semiconductor laminar structure 101 and the second doping region in the semiconductor substrate 102. The implant region 733 may be formed in proximity to the region of the semiconductor laminar structure 101 at which the shorting contact areas of the electrically conductive contact structure 105 are to be formed, for example.

FIG. 7I shows schematic illustrations 790T, 790U, 790V of the removal of the photoresist layer formed over the semiconductor substrate 102, for example. For example, photoresist layer may be stripped or removed from the first surface of the semiconductor substrate 102.

FIG. 7J shows schematic illustrations 7100T, 7100U, 7100V of a deposition of further electrically non-conductive material 312 over the semiconductor substrate 102. The electrically non-conductive material 312 may be a HDP oxide layer, for example. The HDP oxide layer may cover or embed the semiconductor laminar structures 101 formed on the first surface of the semiconductor substrate 102 and any layers (e.g. the electrically conductive gate structure 311 and the gate oxide layer 331) formed on the sidewalls of the semiconductor laminar structures 101, for example. In the regions (e.g. regions V) of the semiconductor laminar structures 101 at which the shorting contact areas of the electrically conductive contact structure 105 are to be formed, the HDP oxide layer 312 may be arranged or formed directly on the sidewalls of the semiconductor laminar structure 101, for example. In the regions (e.g. regions U) of the semiconductor laminar structures 101 which are to be free from the shorting contact areas of the electrically conductive contact structure 105, the gate oxide layer 331 and the electrically conductive gate structure 331 may be formed between the sidewalls and the HDP oxide layer 312, for example. The exposed vertical edges of the gate oxide 331 and gate metal 311 may be insulated using the HDP oxide layer 312 for example.

FIG. 7K shows schematic illustrations 7110T, 7110U, 7110V of a lithography process. The cross-sectional view 7110V shows the exposed regions of the semiconductor laminar structures 101 at which the shorting contact areas of the electrically conductive contact structure 105 are to be formed. The cross-sectional view 7110U shows the other regions (U) of the semiconductor laminar structures 101 covered with a lithography mask material 742.

The exposed regions in the lithography process 7100 (e.g. at regions V) may be smaller than the exposed regions in the lithography process 760 so that electrically conductive material remains between the shorting contact area of the electrically conductive contact structure 105 to be formed and a laterally adjacent electrically conductive gate structure, for example.

FIG. 7L shows schematic illustrations 71201, 7120U, 7120V of an etching of the HDP oxide layer 312 to remove portions of the HDP oxide layer 312 formed on the top walls of the semiconductor laminar structures 101 in the regions (V) at which shorting contact areas of the electrically conductive contact structure 105 are to be formed. Using the lithography process from a smaller area, the HDP oxide layer 312 may be etched away to form an opening. Furthermore, the etching may be carried out so that portions of the HDP oxide layer 312 formed on the sidewalls of the semiconductor laminar structures 101 may be removed. The etching may be controlled (e.g. a fixed time oxide etch) so that portions of HDP oxide layer 312 may remain at bottom portions of the sidewalls of the semiconductor laminar structures 101, for example. For example, portions of the HDP oxide layer 312 may remain on the semiconductor substrate 102 between neighboring semiconductor laminar structures 101, for example. The HDP oxide layer 312 may also cover the implant region, for example.

FIG. 7M shows schematic illustrations 71301, 7130U, 7130V of the removal of the photoresist layer formed over the semiconductor substrate 102, for example. For example, photoresist layer may be stripped or removed from the first surface of the semiconductor substrate 102.

FIG. 7N shows schematic illustrations 71401, 7140U, 7140V of the polishing of the HDP oxide layer 312 formed in the regions (e.g. regions U) of the semiconductor laminar structures 101 which are to be free from shorting contact areas of the electrically conductive contact structure 105. Using CMP, the top edge of the trenches (or the top walls 307 of the semiconductor laminar structures 101) in the regions (U) may be exposed, for example.

FIG. 7O shows schematic illustrations 71501, 7150U, 7150V of the implantation of dopant atoms (e.g. donor atoms) of the first doping regions 103 of the FET structures in the semiconductor laminar structures 101 (e.g. in the regions U and the regions V).

The first doping regions 103 may be formed between the body region 104 of the FET structures in the semiconductor laminar structures 101 and the top walls 307 of the semiconductor laminar substrates, for example. The laterally extending first doping regions 103 may extend along the length, L, of the semiconductor laminar structures 101, for example. The laterally extending first doping regions 103 may provide the first doping regions 103 of a plurality of FET structures of the semiconductor device, for example.

FIG. 7P shows schematic illustrations 7160T, 7160U, 7160V of the formation of the electrically conductive contact structure 105 to form the semiconductor device

The electrically conductive contact structure 105 may be formed by depositing (source) metal over the top walls 307 of the semiconductor laminar structures 101 which are exposed. The metal may be deposited over the exposed top side of the semiconductor laminar structure and through the openings etched (or exposed part of the sidewalk in regions (V), for example.

The portions of the metal for forming the electrically conductive contact structure 105 that may be deposited on the top walls 307 of the semiconductor laminar structures 101, may be electrically connected with the first doping region 103 of the field effect transistor (e.g. may form a source contact 105S), for example. Additionally, portions of the metal for forming the electrically conductive contact structure 105 that may be deposited over exposed regions of the sidewalls of the semiconductor laminar structures 101 in the regions (e.g. regions V) of the semiconductor laminar structures 101, may form contact areas 105R with the body region 104 and the first doping region 103 of the field effect transistor structure at or on the sidewalls of the semiconductor laminar structure 101. The contact areas 105 R between the electrically conductive contact structure 105 and the body region 104 and the first doping region 103 of the field effect transistor structure may provide a source-body short contact at or on the sidewalls of the semiconductor laminar structure 101, for example. The metal deposited in the opening may form a short circuit between the source and the body. These sideways short-circuiting of a source region and a body region along the double sided gate may lead to the formation of a trench based Fin-FET.

The semiconductor devices described in connection with FIGS. 1 to 3 may be formed by at least part of the method described in connection with FIGS. 7A to 7P, for example.

More details and aspects are mentioned in connection with the embodiments described above or below. The embodiments shown in FIGS. 7A to 7P may comprise one or more optional additional features corresponding to one or more aspects mentioned in connection with the proposed concept or one or more embodiments described above (e.g. FIGS. 1 to 6) or below.

Various examples relate to vertical silicon nano-pillar or trench based Fin-FETs, for example. Various examples relate to a method for forming a Si-nanopillar and/or Si-Trench based Fin-FET device, for example. Various examples relate to a method for forming a Fin-FET with a source body short. Various examples relate to a method which may allow for the usage of thicker gate oxide, reducing the capacitance of the device in conduction mode, for example.

Aspects and features (e.g. the semiconductor substrate, the semiconductor laminar structure, the first doping region of the field effect transistor, the body region of the field effect transistor, the second doping region of the field effect transistor, the electrically conductive contact structure, the contact areas of the electrically conductive contact structure with the body region and the first doping region of the field effect transistor structure, the gate structures, the electrically insulating material, and the implant region) mentioned in connection with one or more specific examples may be combined with one or more of the other examples.

Example embodiments may further provide a computer program having a program code for performing one of the above methods, when the computer program is executed on a computer or processor. A person of skill in the art would readily recognize that acts of various above-described methods may be performed by programmed computers. Herein, some example embodiments are also intended to cover program storage devices, e.g., digital data storage media, which are machine or computer readable and encode machine-executable or computer-executable programs of instructions, wherein the instructions perform some or all of the acts of the above-described methods. The program storage devices may be, e.g., digital memories, magnetic storage media such as magnetic disks and magnetic tapes, hard drives, or optically readable digital data storage media. Further example embodiments are also intended to cover computers programmed to perform the acts of the above-described methods or (field) programmable logic arrays ((F)PLAs) or (field) programmable gate arrays ((F)PGAs), programmed to perform the acts of the above-described methods.

The description and drawings merely illustrate the principles of the disclosure. It will thus be appreciated that those skilled in the art will be able to devise various arrangements that, although not explicitly described or shown herein, embody the principles of the disclosure and are included within its spirit and scope. Furthermore, all examples recited herein are principally intended expressly to be only for pedagogical purposes to aid the reader in understanding the principles of the disclosure and the concepts contributed by the inventor(s) to furthering the art, and are to be construed as being without limitation to such specifically recited examples and conditions. Moreover, all statements herein reciting principles, aspects, and embodiments of the disclosure, as well as specific examples thereof, are intended to encompass equivalents thereof.

Functional blocks denoted as “means for . . . ” (performing a certain function) shall be understood as functional blocks comprising circuitry that is configured to perform a certain function, respectively. Hence, a “means for s.th.” may as well be understood as a “means configured to or suited for s.th.”. A means configured to perform a certain function does, hence, not imply that such means necessarily is performing the function (at a given time instant).

Functions of various elements shown in the figures, including any functional blocks labeled as “means”, “means for providing a sensor signal”, “means for generating a transmit signal.”, etc., may be provided through the use of dedicated hardware, such as “a signal provider”, “a signal processing unit”, “a processor”, “a controller”, etc. as well as hardware capable of executing software in association with appropriate software. Moreover, any entity described herein as “means”, may correspond to or be implemented as “one or more modules”, “one or more devices”, “one or more units”, etc. When provided by a processor, the functions may be provided by a single dedicated processor, by a single shared processor, or by a plurality of individual processors, some of which may be shared. Moreover, explicit use of the term “processor” or “controller” should not be construed to refer exclusively to hardware capable of executing software, and may implicitly include, without limitation, digital signal processor (DSP) hardware, network processor, application specific integrated circuit (ASIC), field programmable gate array (FPGA), read only memory (ROM) for storing software, random access memory (RAM), and non-volatile storage. Other hardware, conventional and/or custom, may also be included.

It should be appreciated by those skilled in the art that any block diagrams herein represent conceptual views of illustrative circuitry embodying the principles of the disclosure. Similarly, it will be appreciated that any flow charts, flow diagrams, state transition diagrams, pseudo code, and the like represent various processes which may be substantially represented in computer readable medium and so executed by a computer or processor, whether or not such computer or processor is explicitly shown.

Furthermore, the following claims are hereby incorporated into the Detailed Description, where each claim may stand on its own as a separate embodiment. While each claim may stand on its own as a separate embodiment, it is to be noted that—although a dependent claim may refer in the claims to a specific combination with one or more other claims—other embodiments may also include a combination of the dependent claim with the subject matter of each other dependent or independent claim. Such combinations are proposed herein unless it is stated that a specific combination is not intended. Furthermore, it is intended to include also features of a claim to any other independent claim even if this claim is not directly made dependent to the independent claim.

It is further to be noted that methods disclosed in the specification or in the claims may be implemented by a device having means for performing each of the respective acts of these methods.

Further, it is to be understood that the disclosure of multiple acts or functions disclosed in the specification or claims may not be construed as to be within the specific order. Therefore, the disclosure of multiple acts or functions will not limit these to a particular order unless such acts or functions are not interchangeable for technical reasons. Furthermore, in some embodiments a single act may include or may be broken into multiple sub acts. Such sub acts may be included and part of the disclosure of this single act unless explicitly excluded.

What is claimed is:

1. A semiconductor device, comprising:
a semiconductor laminar structure arranged on a semiconductor substrate, the semiconductor laminar structure comprising a first doping region of a field effect transistor structure and at least a part of a body region of the field effect transistor structure, wherein the body region comprises a first conductivity type and wherein the first doping region comprises a second conductivity type; and
an electrically conductive contact structure providing an electrical contact to the first doping region of the field effect transistor structure and to the body region of the field effect transistor structure at one or more sidewalls of the semiconductor laminar structure.

2. The semiconductor device of claim 1, wherein a lateral dimension of the semiconductor laminar structure is less than 200 nm.

3. The semiconductor device of claim 1, wherein a height of the semiconductor laminar structure is at least 300 nm.

4. The semiconductor device of claim 1, wherein the electrically conductive contact structure extends along the semiconductor laminar structure from a first sidewall of the semiconductor laminar structure to a second sidewall of the semiconductor laminar structure.

5. The semiconductor device of claim 1, wherein a lateral dimension of a part of the electrically conductive contact structure arranged on the one or more sidewalls of the semiconductor laminar structure lies between 150 nm and 300 nm.

6. The semiconductor device of claim 1, wherein the electrically conductive contact structure is in contact with the first doping region of the field effect transistor structure on a top wall of the semiconductor laminar structure.

7. The semiconductor device of claim 1, further comprising at least one gate structure arranged on the one or more sidewalls of the semiconductor laminar structure, wherein the gate structure is arranged with a lateral offset to a contact area of the electrically conductive contact structure with the body region and the first doping region of the field effect transistor structure at the one or more sidewalls of the semiconductor laminar structure.

8. The semiconductor device of claim 7, wherein the lateral offset between the gate structure and the contact area of the electrically conductive contact structure with the body region and the first doping region of the field effect transistor structure is in a range between 30 nm and 100 nm.

9. The semiconductor device of claim 1, wherein the electrically conductive contact structure comprises a plurality of laterally separated contact areas with the body region and the first doping region of the field effect transistor structure arranged on the one or more sidewalls of the semiconductor laminar structure.

10. The semiconductor device of claim 9, further comprising a plurality of gate structures, wherein at least one gate structure is arranged laterally between neighboring contact areas of the plurality of laterally separated contact areas.

11. The semiconductor device of claim 9, wherein a lateral distance between neighboring contact areas of the plurality of laterally separated contact areas along the one or more sidewalls of the semiconductor laminar structure is in a range between 300 nm and 1 μm.

12. The semiconductor device of claim 9, wherein neighboring contact areas of the plurality of laterally separated contact areas are separated by a lateral distance of V_{BD} /100×10 nm along the one or more sidewalls of the semiconductor laminar structure, wherein V_{BD} is a value representing a breakdown voltage of the semiconductor device.

13. The semiconductor device of claim 1, further comprising an implant region formed in the semiconductor substrate, wherein the implant region and the body region are disposed in the semiconductor laminar structure and ohmically connected to each other.

14. The semiconductor device of claim 1, further comprising a plurality of laterally separated implant regions formed in the semiconductor substrate, wherein the implant regions are arranged in proximity to contact areas of the electrically conductive contact structure with the body region and the first doping region of the field effect transistor structure at the one or more sidewalls of the semiconductor laminar structure.

15. The semiconductor device of claim 13, wherein each implant region has a doping of the first conductivity type and an average doping concentration of at least 1×10¹⁸ dopant atoms per cm³.

16. The semiconductor device of claim 13, wherein a lateral dimension of the implant regions is larger than a minimal lateral dimension of the semiconductor laminar structure.

17. The semiconductor device of claim 1, wherein the body region of the field effect transistor structure formed in the semiconductor laminar structure has an average doping concentration of at least 1×10¹⁷ dopant atoms per cm³.

18. A semiconductor device, comprising:
a semiconductor laminar structure arranged on a semiconductor substrate, the semiconductor laminar structure comprising a first doping region of a field effect transistor structure and at least a part of a body region of the field effect transistor structure, wherein the body region comprises a first conductivity type and wherein the first doping region comprises a second conductivity type,
wherein the semiconductor substrate comprises a second doping region of the field effect transistor structure, the second doping region comprising a second conductivity type,
wherein a minimum lateral dimension of the semiconductor laminar structure is less than 200 nm.

19. The semiconductor device of claim 18, further comprising at least one gate structure arranged on at least one sidewall of the semiconductor laminar structure so that the semiconductor laminar structure is depletable in an off-state.

20. A method for forming a semiconductor device, the method comprising:
forming a gate structure of a field effect transistor structure on one or more sidewalls of a semiconductor laminar structure; and
forming an electrically conductive contact structure in contact with a doping region of the field effect transistor structure in the semiconductor laminar structure at the one or more sidewalls of the semiconductor laminar structure.
